(19) United States
(12) Patent Application Publication
(10) Pub. No.: US 2021/0187919 A1
(43) Pub. Date: Jun. 24, 2021

(54) LAMINATE, METHOD FOR MANUFACTURING LAMINATE, AND CAPACITIVE INPUT DEVICE

(71) Applicant: FUJIFILM Corporation, Tokyo (JP)

(72) Inventors: Tatsuya SHIMOYAMA, Fujinomiya-shi (JP); Kyohei Ogawa, Fujinomiya-shi (JP)

(73) Assignee: FUJIFILM Corporation, Tokyo (JP)

(21) Appl. No.: 17/195,820

(22) Filed: Mar. 9, 2021

Related U.S. Application Data
(63) Continuation of application No. PCT/JP2019/033197, filed on Aug. 26, 2019.

(30) Foreign Application Priority Data
Sep. 28, 2018 (JP) 2018-185731

(51) Int. Cl. B32B 27/08; B32B 5/16; B32B 27/14; G03F 7/038; G03F 7/11

(52) U.S. Cl. CPC B32B 27/08; B32B 5/16; B32B 27/14; G03F 7/038; G03F 7/11; B82Y 30/00; B32B 2264/1024; B32B 2305/72; B32B 2307/40; B32B 2264/301; B32B 2264/302; B32B 2264/1022

(57) ABSTRACT

A laminate includes a base material, an oxide particle-containing layer containing at least one of metal oxide particle selected from the group consisting of a titanium oxide particle and a zirconium oxide particle, and a resin layer which is a cured material of a photosensitive composition provided on a surface of the oxide particle-containing layer and has an internal stress of 1.0 MPa or less and a crosslink density of an ethylenically unsaturated group of a first surface layer portion having a surface in contact with the oxide particle-containing layer of 1.2 mmol/g or more. A method for manufacturing a laminate includes a step of forming a photosensitive layer and a step of forming a resin layer.

### CROSS-REFERENCE TO RELATED APPLICATIONS

This application is a Continuation of PCT International Application No. PCT/JP2019/033197 filed on Aug. 26, 2019, which claims priority under 35 U.S.C § 119(a) to Japanese Patent Application No. 2018-185731 filed on Sep. 28, 2018. Each of the above application(s) is hereby expressly incorporated by reference, in its entirety, into the present application.

### BACKGROUND OF THE INVENTION

### 1. Field of the Invention

The present disclosure relates to a laminate, a method for manufacturing a laminate, and a capacitive input device.

### 2. Description of the Related Art

In recent years, in electronic devices such as a mobile phone, a car navigator, a personal computer, a ticket vending machine, or a terminal of the bank, a tablet type input device is disposed on a surface of a liquid crystal device or the like. There is provided a device to which information corresponding to an instruction image is input, by touching a portion, where the instruction image is displayed, with fingers or a touch pen, while referring to the instruction image displayed in an image display region of a liquid crystal device.

The input device described above (hereinafter, also referred to as a touch panel) may include a resistance film type input device, a capacitive input device, and the like.

The capacitive input device is advantageous in that a transmittance conductive film may be simply formed on one sheet of substrate. In such a capacitive input device, there is provided a device in which electrode patterns are extended in directions intersecting each other, and which detects an input position by detecting a change of electrostatic capacity between electrodes, in a case where a finger or the like is touched.

In a case of using these capacitive input devices, in a case of visually recognizing a surface of a touch panel on a position slightly separated from a vicinity of a regular reflected portion of incidence ray from a light source, electrode patterns present in the device are visually recognized, and this may cause an appearance defect. Accordingly, it is necessary to improve concealing properties of the electrode patterns on the surface of a touch panel or the like.

From a viewpoint of maintaining good appearance of the capacitive input device, it is suitable to provide a transparent layer containing metal oxide particles such as titania or zirconia on a surface of a substrate.

Various technologies have been proposed in the related art as a method for forming a cured film using a photosensitive composition, and, for example, a pattern forming method including a firm sticking protective layer forming step of forming a firm sticking protective layer including a polymerizable group and having a light transmittance of light at a wavelength of 193 nm of 80% or more on a substrate, a resist film forming step of applying a radiation sensitive resin composition on the firm sticking protective layer to form a resist film, an exposure step of exposing the resist film, and a development step of developing the exposed resist film to form a pattern, in which pattern collapse or the like of the pattern is suppressed even in a case where a fine pattern having a high aspect ratio is formed (for example, see JP2014-202969A).

In addition, an underlayer forming composition for imprinting containing (A) a resin having a weight-average molecular weight of 1,000 or more containing an ethylenically unsaturated group (P) and a cyclic ether group (T) selected from an oxylanyl group and an oxetanyl group, and (B) a solvent is disclosed, and it is disclosed that an underlayer film having excellent surface flatness and adhesiveness can be formed (for example, see

### SUMMARY OF THE INVENTION

As described above, a technology for enhancing adhesiveness between a substrate and a layer provided on the substrate has been widely studied in the related art, and a technology capable of holding the layer on the substrate regardless of a shape or a size of a pattern has been proposed.

Meanwhile, as described above, a substrate containing metal oxide particles such as titania (titanium oxide) or zirconia (zirconium oxide) on a surface may be used, and in a case of forming a cured layer by providing a photosensitive layer on the surface of the substrate on which the metal oxide particles are present, an expected curing reaction may not be exhibited, compared to a substrate with no particles such as titania. In such a situation, a decrease in curing properties is applied to a part where it is difficult to obtain adhesiveness in the first place, and the adhesiveness of the cured layer to the substrate is significantly decreased. As a result, a phenomenon such as peeling from the substrate is more likely to occur.

The disclosure has been made in view of the above circumstance.

According to an aspect of the disclosure, there is provided a laminate having excellent adhesiveness between an oxide particle-containing layer on a base material and a resin layer.

According to another aspect of the disclosure, there is provided a method for manufacturing a laminate capable of improving the adhesiveness between an oxide particle-containing layer on a base material and a resin layer.

According to still another aspect of the disclosure, there is provided a capacitive input device having excellent adhesiveness between an oxide particle-containing layer on a base material and a resin layer and exhibiting an excellent image display function.

Specific units for achieving the objects described above include the following aspects.

<1> A laminate comprising: a base material;

an oxide particle-containing layer which is provided on the base material and contains at least one of metal oxide particle selected from the group consisting of a titanium oxide particle and a zirconium oxide particle; and

a resin layer which is a cured material of a photosensitive composition, the cured material being provided on a surface of the oxide particle-containing layer, and in which an internal stress is 1.0 MPa or less and

a crosslink density of an ethylenically unsaturated group of a first surface layer portion having a surface in contact with the oxide particle-containing layer is 1.2 mmol/g or more.

<2> The laminate according to <1>, in which the resin layer has a laminated structure of two or more layers.

<3> The laminate according to <2>, in which a thickness of the resin layer in contact with the oxide particle-containing layer is 1μm or less in the laminated structure of two or more layers.

<4> The laminate according to any one of <1> to <3>, in which a total thickness of the resin layer is 10 μm or less.

<5> The laminate according to any one of <1> to <4>, in which, in the resin layer, the crosslink density D1 of the ethylenically unsaturated group of the first surface layer portion and a crosslink density D2 of an ethylenically unsaturated group of a second surface layer portion on a side of the resin layer opposite to a side of the first surface layer portion satisfy a relationship of D1>D2.

<6> The laminate according to any one of <1> to <5>, in which the resin layer contains a resin having a thioether bond.

<7> The laminate according to any one of <1> to <6>, in which the resin layer is brought into contact with at least one conductive member of an electrode for a touch panel or a wire for a touch panel to be used as a protective material of the conductive member.

<8> A capacitive input device comprising the laminate according to <7>.

<9> A method for manufacturing a laminate, the method comprising: a step of forming a photosensitive layer containing a compound including an ethylenically unsaturated group on an oxide particle-containing layer of a base material having the oxide particle-containing layer, the oxide particle-containing layer containing at least one of metal oxide particle selected from the group consisting of a titanium oxide particle and a zirconium oxide particle; and a step of exposing and curing the formed photosensitive layer to form a resin layer in which an internal stress is 1.0 MPa or less and a crosslink density of an ethylenically unsaturated group of a first surface layer portion having a surface in contact with the oxide particle-containing layer is 1.2 mmol/g or more.

<10> The method for manufacturing a laminate according to <9>, in which the photosensitive layer further contains a photopolymerization initiator.

<11> The method for manufacturing a laminate according to <9> or <10>, in which the photosensitive layer further contains a thiol compound.

<12> The method for manufacturing a laminate according to <11>, in which the thiol compound is a di- or higher functional thiol compound.

<13> The method for manufacturing a laminate according to any one of <9> to <12>, in which the compound containing the ethylenically unsaturated group contains a compound represented by Formula (1).

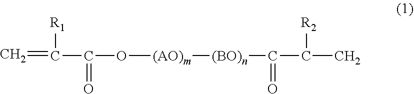

In Formula (1), R₁ and R₂ each independently represent a hydrogen atom or a methyl group, AO and BO each independently represent a different oxyalkylene group having 2 to 4 carbon atoms, and m and n each independently represent an integer of 0 or more and satisfy 4≤m+n≤30.

<14> The method for manufacturing a laminate according to any one of <9> to <13>, in which, in the step of forming of the photosensitive layer, the photosensitive layer is formed on the oxide particle-containing layer by transfer using a transfer film including a temporary support and a photosensitive layer containing a compound containing an ethylenically unsaturated group.

According to an aspect of the invention, there is provided a laminate having excellent adhesiveness between an oxide particle-containing layer on a base material and a resin layer.

According to another aspect of the disclosure, there is provided a method for manufacturing a laminate capable of improving the adhesiveness between an oxide particle-containing layer on a base material and a resin layer.

According to still another aspect of the disclosure, there is provided a capacitive input device having excellent adhesiveness between an oxide particle-containing layer on a base material and a resin layer and exhibiting an excellent image display function.

### DESCRIPTION OF THE PREFERRED EMBODIMENTS

Hereinafter, a laminate and a manufacturing method thereof of the disclosure, and a capacitive input device comprising the laminate of the disclosure will be described in detail. The configuration elements of the embodiment of the disclosure will be described based on the representative embodiments of the disclosure, but the disclosure is not limited to such embodiments.

In the present specification, a numerical range indicated by “to” indicates a range including numerical values before and after “to” as a minimum value and a maximum value, respectively. In a range of numerical values described in stages in the disclosure, the upper limit value or the lower limit value described in a certain range of numerical values may be replaced with an upper limit value or a lower limit value of the range of numerical values described in other stages. In addition, in a range of numerical values described in the disclosure, the upper limit value or the lower limit value of the range of numerical values may be replaced with values shown in the examples.

In a range of numerical values described in stages in this specification, the upper limit value or the lower limit value described in one range of numerical values may be replaced with an upper limit value or a lower limit value of the range of numerical values described in other stages. In addition, in a range of numerical values described in this specification, the upper limit value or the lower limit value of the range of numerical values may be replaced with values shown in the examples.

Regarding a term, group (atomic group) of this disclosure, a term with no description of “substituted” and “unsubstituted” includes both a group not including a substituent and a group including a substituent. For example, an “alkyl group” not only includes an alkyl group not including a substituent (unsubstituted alkyl group), but also an alkyl group including a substituent (substituted alkyl group).

In addition, in the disclosure, “% by mass” is identical to “% by weight” and “part by mass” is identical to “part by weight”.

Further, in the disclosure, a combination of two or more preferable embodiments is the more preferable embodiments.

In the disclosure, in a case where a plurality of substances corresponding to components are present in a composition, an amount of each component in the composition or a layer means a total amount of the plurality of substances present in the composition, unless otherwise noted.

In the disclosure, a term “step” not only includes an independent step, but also includes a step, in a case where the step may not be distinguished from the other step, as long as the expected object of the step is achieved.

In the disclosure, “(meth)acrylic acid” has a concept including both acrylic acid and a methacrylic acid, “(meth)acrylate” has a concept including both acrylate and methacrylate, and “(meth)acryloyl group” has a concept including both acryloyl group and methacryloyl group.

A weight-average molecular weight (Mw) and a number average molecular weight (Mn) of the disclosure, unless otherwise noted, are detected by a gel permeation chromatography (GPC) analysis device using a column of TSKgel GMHxL, TSKgel G4000HxL, TSKgel G2000HxL (all product names manufactured by Tosoh Corporation), by using tetrahydrofuran (THF) as a solvent and a differential refractometer, and are molecular weights obtained by conversion using polystyrene as a standard substance.

In the disclosure, a ratio of the constitutional unit in a resin represents a molar ratio unless otherwise noted.

In the disclosure, the molecular weight, in a case where there is a molecular weight distribution, represents the weight-average molecular weight (Mw), unless otherwise noted.

<Laminate>

The laminate of the disclosure includes at least a base material, an oxide particle-containing layer containing metal oxide particles, and a resin layer which is a cured material of a photosensitive composition provided on a surface of the oxide particle-containing layer, and the oxide particle-containing layer contains at least one kind of particles selected from the group consisting of a titanium oxide particle and a zirconium oxide particle as metal oxide particles.

In addition, in the resin layer of the laminate of the disclosure, an internal stress is 1.0 MPa or less, and a crosslink density of an ethylenically unsaturated group of a first surface layer portion having a surface in contact with the oxide particle-containing layer is 1.2 mmol/g or more.

Further, the laminate of the disclosure may further include another layer, as necessary.

The “resin layer” of the disclosure refers to a cured layer after the photosensitive layer formed of the photosensitive composition is cured.

The “surface layer portion” of the resin layer of the disclosure refers to a portion of the resin layer in a thickness direction including a surface in contact with the oxide particle-containing layer and a portion of 0.1 μm from the surface in the thickness direction, and refers to a portion measured by Attenuated Total Reflectance-infrared spectroscopy (ATR-IR).

As in JP2014-202969A and JP2014-192178A described above, a technology of forming the cured film with the photosensitive composition is widely studied in the related art, and it is found that, for example, in a case where a supporting material containing metal oxide particles such as titania and zirconia is used on a surface, a photosensitive layer is provided on the surface of the supporting material where the metal oxide particles are present. However, in a case of forming a cured layer by providing a photosensitive layer on the surface of the supporting material where the metal oxide particles are present, the expected curing reaction cannot be obtained, compared to the supporting material in which particles such as titania are not present. That is, it is found that, for example, in the vicinity of the surface of the supporting material where the metal oxide particles are present, a reaction of the ethylenically unsaturated group is less likely to proceed, although the surface where the metal oxide particles and the photosensitive layer formed on the surface contain the ethylenically unsaturated group (C═C group).

In such a situation, a decrease in curing properties is applied to a part where it is difficult to obtain adhesiveness in the first place, and the adhesiveness of the cured layer to the supporting material is significantly decreased. As a result, a phenomenon such as peeling from the substrate is more likely to occur.

In order to improve such a situation and increase the adhesiveness between the surface on which the metal oxide particles are present and the resin layer obtained by curing the photosensitive layer formed on the surface, it is important that the internal stress of the cured resin layer is suppressed not to be extremely high (that is, to be soft, not brittle) and the crosslink density of the surface layer portion of the resin layer on the supporting material side (C═C reaction amount) is high.

In view of such circumstances, in the disclosure, the resin layer having the internal stress of 1.0 MPa or less and the crosslink density of the surface layer portion including the surface in contact with the oxide particle-containing layer of 1.2 mmol/g or more is provided on the oxide particle-containing layer selected from the group consisting of a titanium oxide particles and a zirconium oxide particle which is provided on the base material. Specifically, the crosslink density may be satisfied by, for example, crosslinking associated with a reaction between a C═C group of the oxide particle-containing layer and a C═C group of the resin layer.

In addition, in the resin layer, in a case where the crosslink density of the entire layer increases due to the reaction of all the C═C groups contained in the layer, the internal stress of the entire resin layer increases, and conversely, the adhesiveness may be decreased. Accordingly, regarding the cured resin layer, it is important to increase the crosslink density of the surface layer portion on the base material side (that is, the surface layer portion on the oxide particle-containing layer side), not to extremely increase the crosslink density of the resin layer at a position farther from the surface layer portion with respect to the base material, and decreasing the internal stress lower than that of the surface layer portion on the base material side.

As described above, in the disclosure, it is possible to effectively increase the adhesiveness between the surface, in a case where the metal oxide particles are provided on the base material, and the resin layer which is the cured material of the photosensitive layer, by realizing a balance between the crosslink density of the surface layer portion of the resin layer on the base material side and the internal stress of the resin layer other than the surface layer portion.

Hereinafter, the laminate of the disclosure will be described in detail.

<Base Material>

As a base material, a glass base material or a resin base material is preferable.

In addition, the base material is preferably a transparent base material and more preferably a transparent resin base material. The transparency in the disclosure means that the transmittance of all visible light is 85% or more, preferably 90% or more, and more preferably 95% or more.

A refractive index of the base material is preferably 1.50 to 1.52.

As the glass base material, tempered glass such as GORILLA GLASS (registered trademark) manufactured by Corning Incorporated can be used.

As the resin base material, at least one of a component with no optical strains or a component having high transparency is preferably used, and a base material consisting of a resin such as polyethylene terephthalate (PET), polyethylene naphthalate (PEN), polycarbonate (PC), triacetyl cellulose (TAC), polyimide (PI), polybenzoxazole (PBO), or cycloolefin polymer (COP) is used, for example.

As a material of the transparent base material, a material disclosed in JP2010-086684A, JP2010-152809A, and JP2010-257492A is preferably used.

<Oxide Particle-Containing Layer>

An oxide particle-containing layer containing at least one of metal oxide particle selected from the group consisting of a titanium oxide particle and a zirconium oxide particle is provided on the base material.

As an example of the oxide particle-containing layer, a refractive index adjusting layer for adjusting a refractive index is preferably used.

Among them, titanium oxide is preferable from a viewpoint of more effectively exhibiting the effects of the disclosure. In addition, from a viewpoint of improving a refractive index of the oxide particle-containing layer, zirconium oxide is preferable.

In a case where the refractive index adjusting layer is provided as the oxide particle-containing layer, a transparent electrode pattern of, for example, a base material for a touch panel comprising a transparent electrode pattern which is the base material is hardly recognized (that is, concealing properties of the transparent electrode pattern is more improved). A phenomenon that the transparent electrode pattern is visually recognized, is generally referred to as “see-through”.

Regarding the phenomenon that the transparent electrode pattern is recognized, and the concealing properties of the transparent electrode pattern, JP2014-010814A and JP2014-108541A can be suitably referred to.

The support may be configured with the base material and the oxide particle-containing layer. That is, the oxide particle-containing layer may be provided as an outermost layer on the base material to form a part of the support. In the disclosure, in a case where the oxide particle-containing layer is present as an outermost layer in the support, the adhesiveness that tends to decrease in a case where the resin layer is formed on the support is maintained in an excellent manner, a phenomenon such as peeling of the resin layer from the support can be prevented and high quality and reliability of the laminate or a final product formed of the laminate can be maintained.

The refractive index of the oxide particle-containing layer is preferably higher than the refractive index of the photosensitive layer, from a viewpoint of suppressing the see-through, in a case where an electrode and the like are provided on the base material. The refractive index of the oxide particle-containing layer is preferably equal to or greater than 1.50, more preferably equal to or greater than 1.55, and particularly preferably equal to or greater than 1.60.

An upper limit of the refractive index of the oxide particle-containing layer in this case is not particularly limited, and is preferably equal to or smaller than 2.10, more preferably equal to or smaller than 1.85, even more preferably equal to or smaller than 1.78, and particularly preferably equal to or smaller than 1.74.

The refractive index is a value measured by ellipsometry at a wavelength of 550 nm, unless otherwise specified.

The oxide particle-containing layer may be a layer obtained by curing a photocurable (that is, photosensitive) layer, a layer obtained by curing a thermosetting layer, or a layer obtained by curing both photocurable and thermosetting layers.

A film thickness of the oxide particle-containing layer is preferably equal to or smaller than 300 nm, more preferably equal to or smaller than 200 nm, and particularly preferably equal to or smaller than 100 nm.

In addition, the film thickness of the oxide particle-containing layer is preferably equal to or greater than 20 nm, more preferably equal to or greater than 50 nm, even more preferably equal to or greater than 55 nm, and particularly preferably equal to or greater than 60 nm.

The refractive index of the oxide particle-containing layer is preferably adjusted according to the refractive index of the transparent electrode pattern of, for example, a touch panel or the like.

For example, in a case where the refractive index of the transparent electrode pattern is 1.8 to 2.0, as in a case of the transparent electrode pattern consisting of indium tin oxide (ITO), the refractive index of the oxide particle-containing layer is preferably equal to or greater than 1.60. An upper limit of the refractive index of the oxide particle-containing layer in this case is not particularly limited, and is preferably equal to or smaller than 2.1, more preferably equal to or smaller than 1.85, even more preferably equal to or smaller than 1.78, and particularly preferably equal to or smaller than 1.74. In addition, in a case where the refractive index of the transparent electrode pattern is greater than 2.0, as in a case of the transparent electrode pattern consisting of indium zinc oxide (IZO), for example, the refractive index of the oxide particle-containing layer is preferably 1.70 to 1.85.

A method for controlling the refractive index of the oxide particle-containing layer is not particularly limited, and examples thereof include a method using a resin having a predetermined refractive index alone, a method using a resin and metal oxide particles or metal particles, and a method using a composite of metal salt and a resin.

The oxide particle-containing layer preferably includes at least one kind selected from the group consisting of inorganic particles having a refractive index equal to or greater than 1.50 (more preferably equal to or greater than 1.55, and particularly preferably equal to or greater than 1.60), a resin having a refractive index equal to or greater than 1.50 (more preferably equal to or greater than 1.55, and particularly preferably equal to or greater than 1.60), and a polymerizable monomer having a refractive index equal to or greater than 1.50 (more preferably equal to or greater than 1.55, and particularly preferably equal to or greater than 1.60).

According to this embodiment, the refractive index of the oxide particle-containing layer is easily adjusted to be equal to or greater than 1.50 (more preferably equal to or greater than 1.55, and particularly preferably equal to or greater than 1.60).

The oxide particle-containing layer contains at least one of metal oxide particle selected from the group consisting of titanium oxide particles (particles of TiO₂) and zirconium oxide particles (particles of ZrO₂) and preferably contains ethylenically unsaturated group. In a case where the oxide particle-containing layer contains an ethylenically unsaturated group, it is more preferable that the oxide particle-containing layer further contains a compound containing an ethylenically unsaturated group, and as necessary, a binder polymer is preferably contained.

A particle diameter of the metal oxide particles is not particularly limited and can be suitably selected.

Among them, the particle diameter of the metal oxide particles is an average primary particle diameter, and is preferably in a range of 1 nm to 200 nm, more preferably 2 nm to 80 nm, and even more preferably 3 nm to 60 nm. Here, the average primary particle diameter is calculated by measuring particle diameters of 200 random particles using observation of a transmission electron microscope and arithmetically averaging the measured result. In a case where the shape of the particle is not a spherical shape, the longest side is set as the particle diameter.

Regarding the components contained in the oxide particle-containing layer, components of a curable oxide particle-containing layer disclosed in paragraphs 0019 to 0040 and 0144 to 0150 of JP2014-108541A, and components of a transparent layer disclosed in paragraphs 0024 to 0035 and 0110 to 0112 of JP2014-010814A, and components of a composition including ammonium salt disclosed in paragraphs 0034 to 0056 of WO2016/009980A can be referred to.

In addition, the oxide particle-containing layer preferably includes a metal oxidation inhibitor.

In a case where the oxide particle-containing layer includes the metal oxidation inhibitor, surface treatment can be performed with respect to a member (for example, conductive member formed on a substrate) in a direct contact with the oxide particle-containing layer, in a case of transferring the oxide particle-containing layer onto the substrate (that is, a target to be transferred). This surface treatment applies a metal oxide inhibiting function (protection properties) with respect to the member in a direct contact with the oxide particle-containing layer.

The metal oxidation inhibitor is suitably a compound having a heteroaromatic ring having a nitrogen atom. The compound having a heteroaromatic ring having a nitrogen atom may have a substituent.

The heteroaromatic ring having a nitrogen atom is preferably an imidazole ring, a triazole ring, a tetrazole ring, a thiazole ring, a thiadiazole ring, or a fused ring of any one of these and another aromatic ring, and more preferably an imidazole ring, a triazole ring, a tetrazole ring, or a fused ring of any one of these and another aromatic ring. The “other aromatic ring” forming the fused ring may be a homocyclic ring or a heterocyclic ring, is preferably a homocyclic ring, more preferably a benzene ring or a naphthalene ring, and even more preferably a benzene ring.

The oxide particle-containing layer of the disclosure may include a component other than the components described above.

The other component which can be included in the oxide particle-containing layer is the same as the other component which can be included in the photosensitive layer described above.

The oxide particle-containing layer preferably includes a surfactant as the other component.

The method for forming the oxide particle-containing layer is not particularly limited.

Examples of the method for forming the oxide particle-containing layer include a forming method for applying and, as necessary, drying an oxide particle-containing layer forming composition on a base material, and a method for transferring an oxide particle-containing layer of a transfer film including the oxide particle-containing layer on a temporary support onto a desired substrate.

Specific examples of the coating and drying method are respectively the same as the specific examples of the coating and drying in a case of forming the photosensitive layer which will be described later.

The oxide particle-containing layer forming composition may contain each component of the oxide particle-containing layer.

The oxide particle-containing layer forming composition, for example, includes a binder polymer, an ethylenically unsaturated compound, particles, and a solvent.

As the particles, at least one of metal oxide particle selected from the group consisting of a titanium oxide particle and a zirconium oxide particle is contained.

Regarding the components of the oxide particle-containing layer forming composition, components of a curable oxide particle-containing layer disclosed in paragraphs 0019 to 0040 and 0144 to 0150 of JP2014-108541A, and components of a transparent layer disclosed in paragraphs 0024 to 0035 and 0110 to 0112 of JP2014-010814A, and components of a composition including ammonium salt disclosed in paragraphs 0034 to 0056 of WO2016/009980A can be referred to.

<Resin Layer>

The laminate of the disclosure includes a resin layer which is a cured material of the photosensitive composition. The resin layer is provided on the surface of the oxide particle-containing layer, and may have any of a single-layer structure or a multi-layer structure (a laminated structure of a plurality of layers).

The internal stress of the resin layer is 1.0 MPa or less.

In a case where the crosslink density of the entire layer is excessively increased by increasing the reaction amount of C═C groups contained in the resin layer, the entire resin layer is excessively hard and this causes a decrease in adhesiveness. Accordingly, the resin layer of the disclosure includes an intermediate layer portion excluding the surface layer portion maintained in a comparatively soft state by setting the internal stress to 1.0 MPa or less, and contributes to improvement of the adhesiveness between the oxide particle-containing layer on the base material and the resin layer by increasing the crosslink density of the surface layer portion to 1.2 mmol/g or more.

The internal stress of the resin layer is preferably 0.7 MPa or less, more preferably 0.5 MPa or less, even more preferably 0.3 MPa or less, and particularly preferably 0.2 MPa or less. The lower limit value of the internal stress is not limited, and may be 0 MPa.

The internal stress of the disclosure indicates a stress of the resin layer itself, and in a case where the resin layer consists of a plurality of layers, the stress indicates an internal stress of the entire layer consisting of the plurality of layers.

The internal stress is a value measured by the following method.

Using a scanning white light interference microscope (for example, NewView5020 manufactured by Zygo Corporation), a surface shape in the vicinity of a center of the surface of the substrate is measured (for example, in Micro mode), and a difference in height between a highest (or lowest) point and a point separated from this point by 0.5 mm in a plane direction is calculated to convert into a radius of curvature of warping of the substrate. An internal stress s of the resin layer is calculated from the following Stoney's equation by using a radius of curvature R, a modulus of elasticity of the substrate (modulus of elasticity calculated by an inclination of a linear region of an S—S curve of a tensile test) Es, a Poisson's ratio vs of the substrate, a thickness is of the substrate, and a thickness Ta of the resin layer.

s=Es×ts²/(6×(1−vs)×R×Ta): Stoney's equation

The internal stress of the resin layer can be adjusted by suitably selecting the components (ethylenically unsaturated compound, photopolymerization initiator, binder polymer, and the like) contained in the resin layer.

For example, in a case of maintaining the internal stress of the resin layer low, the internal stress can be adjusted to be low, by selecting at least one of decreasing a content of the ethylenically unsaturated compound, increasing a content of the binder polymer, containing a thiol compound, or containing the compound containing the ethylenically unsaturated group represented by Formula (1).

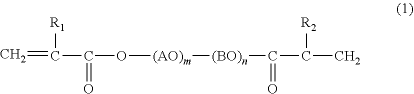

In Formula (1), R₁ and R₂ each independently represent a hydrogen atom or a methyl group, AO and BO each independently represent a different oxyalkylene group having 2 to 4 carbon atoms, and m and n each independently represent an integer of 0 or more and satisfy 4≤m+n≤30.

The details of the compound containing the ethylenically unsaturated group represented by Formula (1) will be described later.

In the resin layer, the crosslink density of the ethylenically unsaturated group of the first surface layer portion having the surface in contact with the oxide particle-containing layer is 1.2 mmol/g or more.

By setting the crosslink density to 1.2 mmol/g or more and increasing the number of crosslink structures formed between the oxide particle-containing layer on the base material and the resin layer, the adhesiveness between the oxide particle-containing layer on the base material and the resin layer is increased by combining with the balance with the internal stress.

The crosslink density of the resin layer is preferably 1.3 mmol/g or more, more preferably 1.5 mmol/g or more, even more preferably 2.0 mmol/g or more, and particularly preferably 2.5 mmol/g or more. The upper limit value of the crosslink density can be 6.0 mmol/g.

The crosslink density of the resin layer is a value obtained by the following method.

A pressure sensitive adhesive tape (for example, #600 manufactured by 3M Japan Ltd.) is attached to the surface of the resin layer of the laminate, and the resin layer is peeled off from the base material with the pressure sensitive adhesive tape. A peeling surface of the peeled resin layer is measured by ATR-IR (Attenuated Total Reflectance-infrared spectroscopy); detector: MCT, crystal: Ge, wave number resolution: 4 cm⁻¹, integration: 32 times) using a fully automatic microscopic FT-IR system LUMOS (manufactured by Bruker Optics), and a peak surface area of 810 cm⁻¹ corresponding to a peak of a double bond is calculated to obtain an area value Y1. Separately, a surface of the photosensitive layer (layer formed of the photosensitive composition) used for forming the resin layer of the laminated is measured by ATR-IR in the same manner as described above, and a peak surface area of 810 cm⁻¹ is calculated to obtain an area value Y2. The crosslink density is calculated by Equation 1 using the obtained area values Y1 and Y2.

The crosslink density calculated by Equation 1 represents the crosslink density of the ethylenically unsaturated group of the surface layer portion (first surface layer portion) of the resin layer having the surface in contact with the oxide particle-containing layer.

Crosslink density [mmol/g]=(Theoretical double bond equivalent [mmol/g] contained in 1 g of solid content of the photosensitive composition (or photosensitive layer))×(Y2−Y1)/Y2 (Equation 1)

The resin layer can be configured as a multi-layer having a laminated structure of two or more layers.

In a case where the resin layer has multiple layers, each layer may be divided into a portion having an internal stress of 1.0 MPa or less and a portion having a crosslink density of the ethylenically unsaturated group of 1.2 mmol/g or more.

Specifically, for example, in a case where the resin layer is formed of two layers, multiple layers including a layer A having an internal stress of 1.0 MPa or less and a layer B having a crosslink density of the ethylenically unsaturated group of 1.2 mmol/g or more may be used. In addition, multiple layers of three or more layers including the layer A, the layer B, and another layer C may be formed.

In a case where the resin layer has a laminated structure of two or more layers, for example, the laminated structure of two layers can be determined by observing a cross section of the resin layer and confirming presence or absence of an interface between the two layers.

In a case where the resin layer has a laminated structure of two or more layers, a thickness of the layer in contact with the oxide particle-containing layer on the base material (for example, the layer B described above) is preferably 1 μm or less. The layer in contact with the oxide particle-containing layer on the base material is provided as a layer having a high crosslink density. From a viewpoint of the effect of improving the adhesiveness between the resin layer and the oxide particle-containing layer on the base material, it is important to increase the reaction amount of the C═C groups (increase the crosslink density), however, it is desirable that the entire resin layer has a small internal stress, and accordingly, a thickness of a layer (that is, layer closest to the oxide particle-containing layer) which contributes to the crosslink with the oxide particle-containing layer is preferably thin.

The thickness of the layer in contact with the oxide particle-containing layer on the base material is more preferably 0.1 μm to 1 μm and even more preferably 0.3 μm to 0.7 μm.

In addition, in a case where the resin layer has a laminated structure of two layers, for example, a ratio of thicknesses (layer B/layer A) between the layer A having an internal stress of 1.0 MPa or less and the layer B having a crosslink density of the ethylenically unsaturated group of 1.2 mmol/g or more is preferably 0.1/10 to 1/5 and more preferably 0.1/9 to 0.5/7.

A total thickness of the resin layer is preferably 20 μm or less and more preferably 10 μm or less.

Here, the total thickness means a thickness of a single resin layer, in a case where the resin layer is a single layer, and means a total of a plurality of resin layers, in a case where the resin layer consists of a plurality of layers of two or more layers.

The thinner the resin layer, the smaller the internal stress. Therefore, by setting the total thickness of the resin layer to 10 μm or less, the effect of improving the adhesiveness with the oxide particle-containing layer on the base material can be easily obtained.

The lower limit of the total thickness of the resin layer is preferably 1 μm or more and more preferably 2 μm or more, from a viewpoint of reliability (water vapor permeability).

In the resin layer, it is preferable that a crosslink density D1 of the ethylenically unsaturated group of the first surface layer portion and a crosslink density D2 of an ethylenically unsaturated group of a second surface layer portion on a side of the resin layer opposite to a side of the first surface layer portion satisfy a relationship of D1>D2.

From a viewpoint of the effect of improving the adhesiveness between the resin layer and the oxide particle-containing layer on the base material, it is important to increase the reaction amount of the C═C groups (increase the crosslink density) in the first surface layer portion. Accordingly, it is preferable that the crosslink density D1 of the resin layer is greater than the crosslink density D2.

The resin layer can be formed by using a resin layer forming composition containing a compound having an ethylenically unsaturated group (an ethylenically unsaturated compound), and as will be described later, the resin layer forming composition preferably further contains a photopolymerization initiator, a thiol compound, and the like.

The details of the resin layer forming composition used for forming the resin layer will be described later.

The resin layer preferably contains a resin having a thioether bond.

As will be described later, the resin layer is preferably a cured layer obtained by curing a photosensitive layer formed by using a resin layer forming composition containing at least an ethylenically unsaturated compound and a thiol compound. Since a resin containing a thioether bond (—S—) is formed in this cured layer, the internal stress of the resin layer can be adjusted to be low. Therefore, the effect of improving the adhesiveness with the oxide particle-containing layer on the base material can be easily obtained.

The resin layer of the disclosure can be brought into contact with at least one conductive member of an electrode for a touch panel or a wire for a touch panel to be suitably used as a protective material of the conductive member.

<Method for Manufacturing Laminate>

A method for manufacturing a laminate includes: a step of forming a photosensitive layer containing a compound containing an ethylenically unsaturated group on an oxide particle-containing layer of a base material containing the oxide particle-containing layer containing at least one of metal oxide particle selected from the group consisting of a titanium oxide particle and a zirconium oxide particle (hereinafter, photosensitive layer forming step); and a stpe of exposing and curing the formed photosensitive layer to form a resin layer having an internal stress of 1.0 MPa or less and a crosslink density of an ethylenically unsaturated group of a first surface layer portion having a surface in contact with the oxide particle-containing layer of 1.2 mmol/g or more (hereinafter, resin layer forming step).

The method for manufacturing the laminate of the disclosure may further include other steps, as necessary.

(Photosensitive Layer Forming Step)

In the photosensitive layer forming step in the disclosure, the photosensitive layer containing the compound having the ethylenically unsaturated group is formed on the oxide particle-containing layer of the base material including the oxide particle-containing layer containing at least one of metal oxide particle selected from the group consisting of a titanium oxide particle and a zirconium oxide particle.

The details of the base material and the oxide particle-containing layer containing at least one of metal oxide particle selected from the group consisting of a titanium oxide particle and a zirconium oxide particle are as described above.

In addition, the details of the components of the compound containing the ethylenically unsaturated group contained in the photosensitive layer will be described later.

A thickness of the photosensitive layer is preferably 20 μm or less, more preferably 15 μm or less, and particularly preferably 10 μm or less.

It is advantageous in a case where the thickness of the photosensitive layer is 20 μm or less, from viewpoints of improving the adhesiveness with the oxide particle-containing layer, reducing a thickness of the entire laminate, improving transmittance of the photosensitive layer or the cured layer to be obtained, and suppressing yellow coloration of the photosensitive layer or the cured layer to be obtained. From a viewpoint of manufacturing suitability, the thickness of the photosensitive layer is preferably 0.5 μm or more, more preferably 1 μm or more, and particularly preferably 2 μm or more.

A refractive index of the photosensitive layer is preferably 1.47 to 1.56, more preferably 1.48 to 1.55, even more preferably 1.49 to 1.54, and particularly preferably 1.50 to 1.53.

In the disclosure, the “refractive index” indicates a refractive index at a wavelength of 550 nm.

The “refractive index” in the disclosure means a value measured with visible light at a wavelength of 550 nm at a temperature of 23° C. by ellipsometry, unless otherwise noted.

The formation of the photosensitive layer in the photosensitive layer forming step may be performed by any of a method for applying a photosensitive composition containing a compound having an ethylenically unsaturated group onto an oxide particle-containing layer on a base material and drying the photosensitive composition, as necessary, or a method for transferring a photosensitive layer onto an oxide particle-containing layer provided on a base material by transfer using a photosensitive transfer material including a temporary support and a photosensitive layer containing a compound containing an ethylenically unsaturated group.

The photosensitive layer of the photosensitive transfer material can be formed by applying the photosensitive composition onto the temporary support and drying it, as necessary.

The method for forming the photosensitive layer is not particularly limited, and a well-known method can be used.

As an example of the method for forming the photosensitive layer, a method forming the photosensitive layer by applying a photosensitive composition containing a solvent onto a base material or a temporary support and then drying, as necessary is used.

As the coating method, a well-known method can be used, and examples thereof include a printing method, a spraying method, a roll coating method, a bar coating method, a curtain coating method, a spin coating method, and a die coating method (that is, slit coating method), and a die coating method is preferable.

As the drying method, a well-known method such as natural drying, heating drying, and drying under reduced pressure can be applied alone or in combination of plural thereof.

Among the above, it is preferable that the photosensitive layer is formed on the oxide particle-containing layer on the base material by transfer using the photosensitive transfer material.

Hereinafter, the embodiment using the photosensitive transfer material will be mainly described.

In this embodiment, the photosensitive layer is formed on the base material by laminating the photosensitive transfer material on the surface of the oxide particle-containing layer on the base material (for example, surface of a side where an electrode or the like of a base material for a touch panel is disposed), and transferring the photosensitive layer of the photosensitive transfer material to the surface of the oxide particle-containing layer.

The laminating (transfer of the photosensitive layer) can be performed using a well-known laminator such as a vacuum laminator or an auto-cut laminator.

As the laminating condition, a general condition can be applied.

The laminating temperature is preferably 80° C. to 150° C., more preferably 90° C. to 150° C., and particularly preferably 100° C. to 150° C.

As described above, in the embodiment using the photosensitive transfer material, even in a case where the laminating temperature is a high temperature (for example, 120° C. to 150° C.), the occurrence of the development residue due to over-heating is suppressed.

In a case of using a laminator comprising a rubber roller, the laminating temperature indicates a temperature of the rubber roller.

A temperature of the substrate in a case of laminating is not particularly limited. The temperature of the substrate at the time of laminating is 10° C. to 150° C., preferably 20° C. to 150° C., and more preferably 30° C. to 150° C. In a case of using a resin substrate as the substrate, the temperature of the substrate at the time of laminating is preferably 10° C. to 80° C., more preferably 20° C. to 60° C., and particularly preferably 30° C. to 50° C.

In addition, linear pressure at the time of laminating is preferably 0.5 N/cm to 20 N/cm, more preferably 1 N/cm to 10 N/cm, and particularly preferably 1 N/cm to 5 N/cm.

In addition, a transportation speed (laminating speed) at the time of laminating is preferably 0.5 m/min to 5 m/min and more preferably 1.5 m/min to 3 m/min.

In a case of using the photosensitive transfer material having a laminated structure of “the protective film/photosensitive layer/interlayer/thermoplastic resin layer/temporary support”, first, the protective film is peeled off from the photosensitive transfer material to expose the photosensitive layer, the photosensitive transfer material and the base material are bonded to each other so that the exposed photosensitive layer and the oxide particle-containing layer on the base material are in contact with each other, and heating and pressurizing are performed. Accordingly, the photosensitive layer of the photosensitive transfer material is transferred onto the base material, and a laminate having a laminated structure of “temporary support/thermoplastic resin layer/interlayer/photosensitive layer/oxide particle-containing layer/base material” is formed. In a case where a base material for a touch panel where an electrode and the like are disposed is used as the base material, among the laminated structure, a laminate having a laminated structure of “temporary support/thermoplastic resin layer/interlayer/photosensitive layer/oxide particle-containing layer/electrode and the like/substrate” is formed.

After that, the temporary support is peeled off from the laminate, as necessary. However, the pattern exposure which will be described later can be also performed, by leaving the temporary support.

As an example of the method for transferring the photosensitive layer of the photosensitive transfer material on the base material for a touch panel and performing pattern exposure and development by using the base material for a touch panel as the base material, a description disclosed in paragraphs 0035 to 0051 of JP2006-023696A can also be referred to.

(Resin Layer Forming Step)

In the resin layer forming step of the disclosure, the resin layer having an internal stress of 1.0 MPa or less, and a crosslink density of an ethylenically unsaturated group of a first surface layer portion having a surface in contact with the oxide particle-containing layer of 1.2 mmol/g or more is formed by exposing and curing the photosensitive layer.

The details of the resin layer are as described above, and the preferred embodiment is also the same. Therefore, the description thereof is omitted here.

In this step, the photosensitive layer is exposed, and the exposed portion of the photosensitive layer is cured to obtain a cured layer.

The expose may be performed in the embodiment of performing the exposure in a pattern shape (pattern exposure), that is, the embodiment in which an exposed portion and an unexposed portion are present. The pattern exposure may be exposed through a mask or may be digital exposure using a laser or the like.

The exposed portion of the photosensitive layer is cured, but, for example, the unexposed portion in the pattern exposure is not cured, and accordingly, the unexposed portion can be removed (dissolved) by a developer in the development step performed after the exposure. The unexposed portion is a portion for forming an opening of the cured layer through the development step.

As a light source, a light source can be suitably selected, as long as it can emit light at a wavelength region (for example, 365 nm or 405 nm) at which the photosensitive layer can be cured. Examples of the light source include various lasers, a light emitting diode (LED), an ultra-high pressure mercury lamp, a high pressure mercury lamp, and a metal halide lamp. An exposure intensity is preferably 5 mJ/cm² to 200 mJ/cm², and more preferably 10 mJ/cm² to 200 mJ/cm².

In a case where the photosensitive layer is formed on the oxide particle-containing layer on the base material using the photosensitive transfer material, the exposure may be performed after peeling the temporary support, or the temporary support may be peeled off after performing the exposure before peeling off the temporary support.

In addition, in the exposure step, the heat treatment (so-called post exposure bake (PEB)) may be performed with respect to the photosensitive layer after the pattern exposure and before the development.

After pattern exposure or the like, the development step of developing the photosensitive layer after exposure can be provided.

In the development step, the cured pattern can be formed by developing the pattern-exposed photosensitive layer (that is, by dissolving the unexposed portion of the pattern exposure with a developer). In a case where the base material for a touch panel having electrodes or the like is used as the base material, an electrode protective film which protects at least a part of the electrodes or the like can be obtained.

A developer used in the development is not particularly limited, and a well-known developer such as a developer disclosed in JP1993-072724A (JP-H5-072724A) can be used.

As the developer, an alkaline aqueous solution is preferably used.

Examples of the alkaline compound which can be included in the alkaline aqueous solution include sodium hydroxide, potassium hydroxide, sodium carbonate, potassium carbonate, sodium hydrogen carbonate, potassium hydrogen carbonate, tetramethyl ammonium hydroxide, tetraethyl ammonium hydroxide, tetrapropyl ammonium hydroxide, tetrabutylammonium hydroxide, and choline (2-hydroxyethyltrimethylammonium hydroxide).

The pH of the alkaline aqueous solution at 25° C. is preferably 8 to 13, more preferably 9 to 12, and particularly preferably 10 to 12.

A content of the alkaline compound in the alkaline aqueous solution is preferably 0.1% by mass to 5% by mass and more preferably 0.1% by mass to 3% by mass with respect to a total mass of the alkaline aqueous solution.

The developer may include an organic solvent having miscibility with water.

Examples of the organic solvent include methanol, ethanol, 2-propanol, 1-propanol, butanol, diacetone alcohol, ethylene glycol monomethyl ether, ethylene glycol monoethyl ether, ethylene glycol mono-n-butyl ether, benzyl alcohol, acetone, methyl ethyl ketone, cyclohexanone, ε-caprolactone, γ-butyrolactone, dimethylformamide, dimethylacetamide, hexamethylphosphoramide, ethyl lactate, methyl lactate, ε-caprolactam, and N-methylpyrrolidone.

A concentration of the organic solvent is preferably 0.1% by mass to 30% by mass.

The developer may include a well-known surfactant. A concentration of the surfactant is preferably 0.01% by mass to 10% by mass.

A liquid temperature of the developer is preferably 20° C. to 40° C.

Examples of the development method include methods such as puddle development, shower development, shower and spin development, and dip development.

In a case of the shower development, the unexposed portion of the photosensitive layer is removed by spraying the developer to the photosensitive layer after the pattern exposure as a shower. In a case of using the photosensitive transfer material comprising at least one of the photosensitive layer, the thermoplastic resin layer, or the interlayer, after the transfer of these layers onto the substrate and before the development of the photosensitive layer, an alkaline solution having a low solubility of the photosensitive layer may be sprayed as a shower, and at least one of the thermoplastic resin layer or the interlayer (both layers, in a case where both layers are present) may be removed in advance.

In addition, after the development, the development residue is preferably removed by spraying a cleaning agent with a shower and rubbing with a brush or the like.

A liquid temperature of the developer is preferably 20° C. to 40° C.

The development step may include a stage of performing the development, and a stage of performing the heat treatment (hereinafter, also referred to as “post baking”) with respect to the cured layer obtained by the development.

In a case where the substrate is a resin substrate, a temperature of the post baking is preferably 100° C. to 160° C. and more preferably 130° C. to 160° C.

A resistance value of the transparent electrode pattern can also be adjusted by this post baking.

In addition, in a case where the photosensitive layer includes a carboxy group-containing (meth)acrylic resin, at least a part of the carboxy group-containing (meth)acrylic resin can be changed to carboxylic acid anhydride by the post baking. This improves developability and strength of the cured layer.

In addition, the development step may include a stage of performing the development, and a stage of exposing the cured layer obtained by the development (hereinafter, also referred to as “post exposure”).

In a case where the development step includes a stage of performing the post exposure and a stage of performing the post baking, the post exposure, and the post baking are preferably performed in this order.

Regarding the pattern exposure and the development, a description disclosed in paragraphs 0035 to 0051 of JP2006-023696A can be referred to, for example.

The preferred manufacturing method of the touch panel of the disclosure may include a step other than the steps described above. As the other step, a step (for example, washing step or the like) which may be provided in a normal photolithography step can be applied without any particular limitations.

Next, the details of the photosensitive composition will be described.

The photosensitive layer of the disclosure can be formed using the photosensitive composition containing at least the compound having an ethylenically unsaturated group (ethylenically unsaturated compound). The photosensitive composition of the disclosure can be prepared by also using a photopolymerization initiator, a thiol compound, a binder polymer, and other components, and among them, a photosensitive composition containing the ethylenically unsaturated compound and the photopolymerization initiator and/or the thiol compound is preferable.

Hereinafter, the components contained in the photosensitive composition (or photosensitive layer formed by the photosensitive composition) will be described.

(Compound Having Ethylenically Unsaturated Group)

The photosensitive composition of the disclosure preferably contains at least one kind of the compound having an ethylenically unsaturated group (hereinafter, also referred to as an ethylenically unsaturated compound).

The photosensitive composition preferably includes a di- or higher functional ethylenically unsaturated compound as the ethylenically unsaturated compound.

Here, the di- or higher functional ethylenically unsaturated compound refers to a compound having two or more ethylenically unsaturated groups in one molecule.

As the ethylenically unsaturated group, a (meth)acryloyl group is more preferable.

As the ethylenically unsaturated compound, a (meth)acrylate compound is preferable.

From a viewpoint of curable property after curing, the photosensitive composition particularly preferably includes a difunctional ethylenically unsaturated compound (preferably a difunctional (meth)acrylate compound) and a tri- or higher functional ethylenically unsaturated compound (preferably a tri- or higher functional (meth)acrylate compound).

The difunctional ethylenically unsaturated compound is not particularly limited and can be suitably selected from well-known compounds.

Examples of the difunctional ethylenically unsaturated compound include tricyclodecane dimethanol di(meth)acrylate, 1,9-nonanediol di(meth)acrylate, 1,6-hexanediol di(meth)acrylate, polypropylene glycol diacrylate, polytetramethylene glycol diacrylate, and a compound represented by Formula (1).

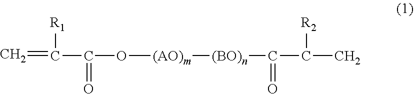

In Formula (1), R₁ and R₂ each independently represent a hydrogen atom or a methyl group and AO and BO each independently represent different oxyalkylene groups having 2 to 4 carbon atoms.

Examples of the oxyalkylene group having 2 to 4 carbon atoms include an oxyethylene group, an oxypropylene group, and an oxybutylene group.

In Formula (1), m and n each independently represent an integer of 0 or more and satisfy 4≤m+n≤30.

Specific examples of the compound represented by Formula (1) are shown below. However, in the disclosure, there is no limitation thereto.

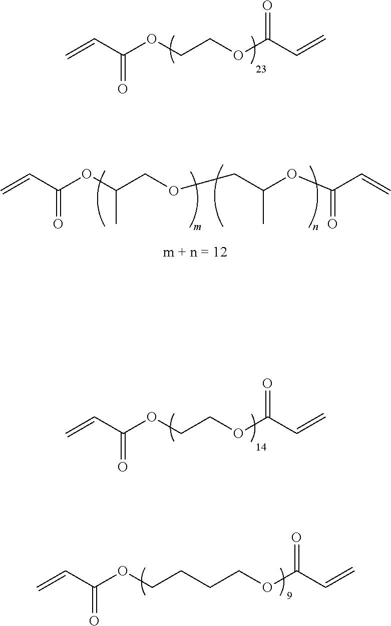

As the difunctional ethylenically unsaturated compound, a commercially available product on the market may be used, and examples of the commercially available product include tricyclodecane dimethanol diacrylate (A-DCP, manufactured by Shin-Nakamura Chemical Co., Ltd.), tricyclodecane dimethanol dimethacrylate (DCP, manufactured by Shin-Nakamura Chemical Co., Ltd.), 1,9-nonanediol diacrylate (A-NOD-N, manufactured by Shin-Nakamura Chemical Co., Ltd.), 1,6-hexanediol diacrylate (A-HD-N, manufactured by Shin-Nakamura Chemical Co., Ltd.), polypropylene glycol diacrylate (APG-700, manufactured by Shin-Nakamura Chemical Co., Ltd.), and polytetramethylene glycol diacrylate (A-PTMG-65, manufactured by Shin-Nakamura Chemical Co., Ltd.)

The tri- or higher functional ethylenically unsaturated compound is not particularly limited and can be suitably selected from well-known compounds.

Examples of the tri- or higher functional ethylenically unsaturated compound include dipentaerythritol (tri/tetra/penta/hexa) (meth)acrylate, pentaerythritol (tri/tetra) (meth)acrylate, trimethylolpropane tri(meth)acrylate, ditrimethylolpropane tetra(meth)acrylate, isocyanuric acid (meth)acrylate, and a (meth)acrylate compound of a glycerin tri(meth)acrylate skeleton.

Here, the “(tri/tetra/penta/hexa) (meth)acrylate” has a concept including tri(meth)acrylate, tetra(meth)acrylate, penta(meth)acrylate, and hexa(meth)acrylate, and the “(tri/tetra) (meth)acrylate” has a concept including tri(meth)acrylate and tetra(meth)acrylate.

Examples of the ethylenically unsaturated compound also include a caprolactone-modified compound of a (meth)acrylate compound (KAYARAD (registered trademark) DPCA-20 manufactured by Nippon Kayaku Co., Ltd., A-9300-1CL manufactured by Shin-Nakamura Chemical Co., Ltd., or the like), an alkylene oxide-modified compound of a (meth)acrylate compound (KAYARAD RP-1040 manufactured by Nippon Kayaku Co., Ltd., ATM-35E, A-9300 manufactured by Shin-Nakamura Chemical Co., Ltd., EBECRYL (registered trademark) 135 manufactured by Daicel-Allnex Ltd., or the like), and ethoxylated glycerin triacrylate (A-GLY-9E manufactured by Shin-Nakamura Chemical Co., Ltd.).

As the ethylenically unsaturated compound, a urethane (meth)acrylate compound (preferably tri- or higher functional urethane (meth)acrylate compound) is also used.

Examples of the tri- or higher functional urethane (meth)acrylate compound include 8UX-015A (manufactured by Taisei Fine Chemical Co., Ltd.), UA-32P (manufactured by Shin-Nakamura Chemical Co., Ltd.), and UA-1100H (manufactured by Shin-Nakamura Chemical Co., Ltd.).

In addition, the ethylenically unsaturated compound preferably includes an ethylenically unsaturated compound having an acid group, from a viewpoint of improving developability.

Examples of the acid group include a phosphoric acid group, a sulfonic acid group, and a carboxy group, and a carboxy group is preferable.

Examples of the ethylenically unsaturated compound including the acid group include a tri- and tetra-functional ethylenically unsaturated compound including the acid group (component obtained by introducing a carboxy group to pentaerythritol tri- and tetra-acrylate (PETA) skeleton (acid value=80 mgKOH/g to 120 mgKOH/g)), and a penta- and hexa-functional ethylenically unsaturated compound including the acid group (component obtained by introducing a carboxy group to dipentaerythritol penta- and hexa-acrylate (DPHA) skeleton (acid value=25 mgKOH/g to 70 mgKOH/g)).

The tri- or higher functional Ethylenically unsaturated compound including the acid group may be used in combination with the difunctional ethylenically unsaturated compound including the acid group, as necessary.

As the ethylenically unsaturated compound including the acid group, at least one kind selected from the group consisting of di- or higher functional ethylenically unsaturated compound including carboxy group and a carboxylic acid anhydride thereof is preferable. This improves developability and hardness of the cured layer.

The di- or higher functional ethylenically unsaturated compound including a carboxy group is not particularly limited and can be suitably selected from well-known compounds.

For example, as the di- or higher functional ethylenically unsaturated compound including a carboxy group, ARONIX (registered trademark) TO-2349 (manufactured by Toagosei Co., Ltd.), ARONIX M-520 (manufactured by Toagosei Co., Ltd.), or ARONIX M-510 (manufactured by Toagosei Co., Ltd.) can be preferably used.

The ethylenically unsaturated compound including the acid group is also preferably a polymerizable compound including an acid group disclosed in paragraphs 0025 to 0030 of JP2004-239942A. The content of this publication is incorporated in this specification.

A weight-average molecular weight (Mw) of the ethylenically unsaturated compound is preferably 200 to 3,000, more preferably 250 to 2,600, even more preferably 280 to 2,200, and particularly preferably 300 to 2, 200.

In addition, a ratio of the content of the ethylenically unsaturated compound having a molecular weight of 300 or less, among the ethylenically unsaturated compound, is preferably 30% by mass or less, more preferably 25% by mass or less, and even more preferably 20% by mass or less, with respect to all of the ethylenically unsaturated compounds included in the photosensitive composition.

The ethylenically unsaturated compound may be used alone or in combination of two or more thereof.

The content of the ethylenically unsaturated compound in the photosensitive composition (or photosensitive layer) is preferably 1% by mass to 70% by mass, more preferably 10% by mass to 70% by mass, even more preferably 20% by mass to 60% by mass, and particularly preferably 20% by mass to 50% by mass, with respect to a solid content amount of the photosensitive composition (or total mass of photosensitive layer).

In addition, in a case where the photosensitive composition (or photosensitive layer) includes a difunctional ethylenically unsaturated compound and a tri- or higher functional ethylenically unsaturated compound, the content of the difunctional ethylenically unsaturated compound is preferably 10% by mass to 90% by mass, more preferably 20% by mass to 85% by mass, and even more preferably 30% by mass to 80% by mass, with respect to all of the ethylenically unsaturated compounds included in the photosensitive composition (or photosensitive layer).

In this case, the content of the tri- or higher functional ethylenically unsaturated compound is preferably 10% by mass to 90% by mass, more preferably 15% by mass to 80% by mass, and even more preferably 20% by mass to 70% by mass, with respect to all of the ethylenically unsaturated compounds included in the photosensitive composition (or photosensitive layer).

In this case, the content of the di- or higher functional ethylenically unsaturated compound is preferably 40% by mass or more and less than 100% by mass, more preferably 40% by mass to 90% by mass, even more preferably 50% by mass to 80% by mass, and particularly preferably 50% by mass to 70% by mass, with respect to a total content of the difunctional ethylenically unsaturated compound and the tri- or higher functional ethylenically unsaturated compound.

In addition, in a case where the photosensitive composition (or photosensitive layer) includes a di- or higher functional ethylenically unsaturated compound, the photosensitive composition (or photosensitive layer) may further include a monofunctional ethylenically unsaturated compound.

Further, in a case where the photosensitive composition (or photosensitive layer) includes a di- or higher functional ethylenically unsaturated compound, the di- or higher functional ethylenically unsaturated compound is preferably the main component in the ethylenically unsaturated compound contained in the photosensitive composition (or photosensitive layer).

Specifically, in a case where the photosensitive composition (or photosensitive layer) includes di- or higher functional ethylenically unsaturated compound, the content of the di- or higher functional ethylenically unsaturated compound is preferably 40% by mass to 100% by mass, more preferably 50% by mass to 100% by mass, and particularly preferably 60% by mass to 100% by mass with respect to a total content of the ethylenically unsaturated compound included in the photosensitive composition (photosensitive layer).

In a case where the photosensitive composition (or photosensitive layer) includes the ethylenically unsaturated compound including an acid group (preferably, di- or higher functional ethylenically unsaturated compound including a carboxy group or a carboxylic acid anhydride thereof), the content of the ethylenically unsaturated compound including the acid group is preferably 1% by mass to 50% by mass, more preferably 1% by mass to 20% by mass, and even more preferably 1% by mass to 10% by mass, with respect to the photosensitive composition (or photosensitive layer).

(Photopolymerization Initiator)

The photosensitive composition of the disclosure preferably contains at least one kind of photopolymerization initiator.

The photopolymerization initiator is not particularly limited and a well-known photopolymerization initiator can be used.

Examples of the photopolymerization initiator include a photopolymerization initiator having an oxime ester structure (hereinafter, also referred to as an “oxime-based photopolymerization initiator”), a photopolymerization initiator having an a-aminoalkylphenone structure (hereinafter, an “α-aminoalkylphenone-based photopolymerization initiator”), a photopolymerization initiator having an α-hydroxyalkylphenone structure (hereinafter also referred to as an “α-hydroxyalkylphenone-based photopolymerization initiator”), a photopolymerization initiator having an acylphosphine oxide structure. (hereinafter, also referred to as an “acylphosphine oxide-based photopolymerization initiator”), and a photopolymerization initiator having an N-phenylglycine structure (hereinafter, “N-phenylglycine-based photopolymerization initiator”).

The photopolymerization initiator preferably includes at least one kind selected from the group consisting of the oxime-based photopolymerization initiator, the a-aminoalkylphenone-based photopolymerization initiator, the α-hydroxyalkylphenone-based photo polymerization initiator, and the N-phenylglycine-based photopolymerization initiator, and more preferably includes at least one kind selected from the group consisting of the oxime-based photopolymerization initiator, the α-aminoalkylphenone-based photopolymerization initiator, and the N-phenylglycine-based photopolymerization initiator.

In addition, as the photopolymerization initiator, for example, polymerization initiators disclosed in paragraphs 0031 to 0042 of JP2011-095716A and paragraphs 0064 to 0081 of JP2015-014783A may be used.

Examples of a commercially available product of the photopolymerization initiator include 1-[4-(phenylthio)-1,2-octanedione-2-(O-benzoyloxime) (product name: IRGACURE (registered trademark) OXE-01, manufactured by BASF Japan Ltd.), 1-[9-ethyl-6-(2-methylbenzoyl)-9H-carbazol-3-yl]ethanone-1-(O-acetyloxime) (product name: IRGACURE OXE-02, manufactured by BASF Japan Ltd.), 2-(dimethylamino)-2-[(4-methylphenyl)methyl]-1-[4-(4-morpholinyl)phenyl]-1-butanone (product name: IRGACURE 379EG, manufactured by BASF Japan Ltd.), 2-methyl-1-(4-methylthiophenyl)-2-morpholinopropan-1-one (product name: IRGACURE 907, manufactured by BASF Japan Ltd.), 2-hydroxy-1-{4-[4-(2-hdroxy-2-methyl-propionyl)-benzyl]phenyl}-2-methyl-propan-1-one (product name: IRGACURE 127, manufactured by BASF Japan Ltd.), 2-benzyl-2-dimethylamino-1-(4-morpholinophenyl)-butanone-1 (product name: IRGACURE 369, manufactured by BASF Japan Ltd.), 2-hydroxy-2-methyl-1-phenyl-propan-1-one (product name: IRGACURE 1173, manufactured by BASF Japan Ltd.), 1-hydroxy cyclohexyl phenyl ketone (product name: IRGACURE 184, manufactured by BASF Japan Ltd.), 2,2-dimethoxy-1,2-diphenylethan-1-one (product name: IRGACURE 651, manufactured by BASF Japan Ltd.), and a product name of an oxime ester type (product name: Lunar 6, manufactured by DKSH Management Ltd.).

The photopolymerization initiator may be used alone or in combination of two or more thereof.

The content of the photopolymerization initiator in the photosensitive composition (or photosensitive layer) is not particularly limited and is preferably 0.1% by mass or more, more preferably 0.2% by mass or more, and even more preferably 0.3% by mass or more with respect to a solid content amount of the photosensitive composition (or total mass of the photosensitive layer).

In addition, the content of the photopolymerization initiator is preferably equal to or smaller than 10% by mass and more preferably equal to or smaller than 5% by mass, with respect to a total mass of the photosensitive composition (or photosensitive layer).

(Blocked Isocyanate Compound)

The photosensitive composition of the disclosure preferably further includes a blocked isocyanate compound, from a viewpoint of hardness after curing.

The blocked isocyanate compound refers to a “compound having a structure in which the isocyanate group of isocyanate is protected (masked) with a blocking agent”.

A dissociation temperature of the blocked isocyanate compound is preferably 100° C. to 160° C. and more preferably 130° C. to 150° C.

The dissociation temperature of blocked isocyanate of the specification is a “temperature at an endothermic peak accompanied with a deprotection reaction of blocked isocyanate, in a case where the measurement is performed by differential scanning calorimetry (DSC) analysis using a differential scanning calorimeter (manufactured by Seiko Instruments Inc., DSC6200)”.

Examples of the blocking agent having a dissociation temperature at 100° C. to 160° C. include a pyrazole compound (3,5-dimethylpyrazole, 3 -methylpyrazole, 4-bromo-3,5-dimethylpyrazole, 4-nitro-3,5-dimethylpyrazole, or the like), an active methylene compound (diester malonate (dimethyl malonate, diethyl malonate, di n-butyl malonate, di-2-ethylhexyl malonate)), a triazole compound (1,2,4-triazole or the like), and an oxime compound (compound having a structure represented by —C(═N—OH)— in a molecule such as formaldoxime, acetoaldoxime, acetoxime, methyl ethyl ketoxime, or cyclohexanone oxime). Among these, from a viewpoint of preservation stability, an oxime compound or a pyrazole compound is preferable, and an oxime compound is particularly preferable.

In addition, it is preferable that the blocked isocyanate compound has an isocyanurate structure, from viewpoints of improving brittleness of the film, improving the adhesion with a transfer target, and the like. The blocked isocyanate compound having an isocyanurate structure can be prepared, for example, by converting hexamethylene diisocyanate into isocyanurate and protecting it.

Among blocked isocyanate compounds having an isocyanurate structure, a compound having an oxime structure using an oxime compound as a blocking agent is preferable, since a dissociation temperature is easily set in a preferable range and the development residue is easily reduced, compared to a compound having no oxime structure.

The blocked isocyanate compound preferably has a polymerizable group and more preferably has a radically polymerizable group, from a viewpoint of hardness after curing.

The polymerizable group is not particularly limited, and well-known polymerizable groups can be used, and examples thereof include a (meth)acryloxy group, a (meth)acrylamide group, an ethylenically unsaturated group such as styryl group, and an epoxy group such as a glycidyl group. Among these, as the polymerizable group, an ethylenically unsaturated group is preferable, and a (meth)acryloxy group is more preferable, from viewpoints of surface shape of the surface of the cured layer to be obtained, a development speed, and reactivity.

As the blocked isocyanate compound, a commercially available product on the market may be used. Examples of the commercially available product include Karenz AOI-BM, Karenz MOI-BM, Karenz, Karenz MOI-BP (all manufactured by Showa Denko K. K.), and a block type Duranate series (manufactured by Asahi Kasei Chemicals Corporation).

A molecular weight of the blocked isocyanate compound is preferably 200 to 3,000, more preferably 250 to 2,600, and particularly preferably 280 to 2,200.

In the disclosure, the blocked isocyanate compound may be used alone or in combination of two or more kinds thereof.

A content of the blocked isocyanate compound is preferably 1% by mass to 50% by mass, and more preferably 5% by mass to 30% by mass, with respect to the solid content amount of the photosensitive composition (or total mass of the photosensitive layer).

(Thiol Compound)

The photosensitive composition of the disclosure preferably contains a thiol compound.

By containing the thiol compound, a thioether bond is present in the cured resin layer, and this is suitable for reducing internal resistance of the resin layer. As a result, the adhesiveness of the resin layer to the oxide particle-containing layer on the base material is improved.

As the thiol compound, a monofunctional thiol compound or a polyfunctional thiol compound is preferably used. Among them, from a viewpoint of hardness after curing, the thiol compound is preferably a di- or higher functional thiol compound (polyfunctional thiol compound) and more preferably a polyfunctional thiol compound.

The polyfunctional thiol compound refers to a compound having two or more mercapto groups (thiol groups) in a molecule. The polyfunctional thiol compound is preferably a low-molecular-weight compound having a molecular weight of 100 or more, and specifically, the molecular weight thereof is more preferably 100 to 1,500 and even more preferably 150 to 1,000.

The number of functional groups of the polyfunctional thiol compound is preferably 2 to 10, more preferably 2 to 8, and even more preferably 2 to 6, from a viewpoint of hardness after curing.

In addition, the polyfunctional thiol compound is preferably an aliphatic polyfunctional thiol compound, from viewpoints of tackiness and bending resistance and hardness after curing.

Further, the thiol compound is more preferably a secondary thiol compound, from a viewpoint of bending resistance and hardness after curing.

Specific examples of the polyfunctional thiol compound include trimethylolpropane tris (3-mercaptobutyrate), 1,4-bis (3-mercaptobutyryloxy) butane, pentaerythritol tetrakis (3-mercaptobutyrate), 1,3,5-tris (3-mercaptobutyryloxyethyl)-1,3,5-triazine-2,4,6 (1H, 3H, 5H)-trione, trimethylolethanetris (3-mercaptobutyrate), tris [(3-mercaptopropionyloxy)ethyl] isocyanurate, trimethylolpropane tris (3-mercaptopropionate), pentaerythritol tetrakis (3-mercaptopropionate), tetraethylene glycol bis (3-mercaptopropionate), dipentaerythritol hexakis (3-mercaptopropionate), ethylene glycol bisthiopropionate, 1,2-benzenedithiol, 1,3-benzenedithiol, 1,2-ethanedithiol, 1,3 -propanedithiol, 1, 6-hexamethylenedithiol, 2,2′-(ethylenedithio) diethanethiol, meso-2,3-dimercaptosuccinic acid, p-xylylenedithiol, m-xylylenedithiol, and di(mercaptoethyl) ether.

Among these, trimethylolpropane tris (3-mercaptobutyrate), 1,4-bis (3-mercaptobutyryloxy) butane, pentaerythritol tetrakis (3-mercaptobutyrate), 1,3,5-tris (3-mercaptobutyryloxyethyl)-1,3,5-triazine-2,4,6 (1H, 3H, 5H)-trione, trimethylolethanetris (3-mercaptobutyrate), tris [(3-mercaptopropionyloxy) ethyl] isocyanurate, trimethylolpropane tris (3-mercaptopropionate), pentaerythritol tetrakis (3-mercaptopropionate), tetraethylene glycol bis (3-mercaptopropionate), and dipentaerythritol hexakis (3-mercaptopropionate) are preferable.

As the monofunctional thiol compound, both an aliphatic thiol compound and an aromatic thiol compound can be used.

Specific examples of the monofunctional aliphatic thiol compound include 1-octanethiol, 1-dodecanethiol, β-mercaptopropionic acid, methyl-3-mercaptopropionate, 2-ethylhexyl-3 -mercaptopropionate, n-octyl-3-mercaptopropionate, methoxybutyl-3-mercaptopropionate, and stearyl-3-mercaptopropionate.

Examples of the monofunctional aromatic thiol compound include benzenethiol, toluenethiol, and xylenethiol.

The thiol compound is preferably a thiol compound having an ester bond and more preferably includes a compound represented by Formula 1, from viewpoints of tackiness, bending resistance, and hardness after curing.

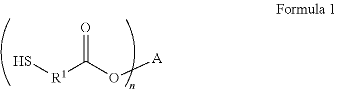

In Formula 1, n represents an integer of 1 to 6, A represents an n-valent organic group having 1 to 15 carbon atoms or a group represented by Formula 2, and R¹'s each independently represent a divalent organic group having 1 to 15 carbon atoms.

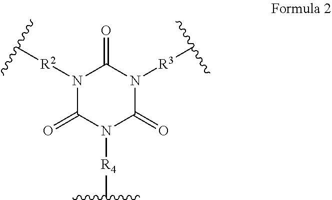

In Formula 2, R² to R⁴ each independently represent a divalent organic group having 1 to 15 carbon atoms, and wavy line parts represent bonding positions to an oxygen atom in Formula 1.

From a viewpoint of hardness after curing, n in Formula 1 is preferably an integer of 2 to 6.

A in Formula 1 is preferably an n-valent aliphatic group having 1 to 15 carbon atoms or a group represented by Formula 2, more preferably an n-valent aliphatic group having 4 to 15 carbon atoms or a group represented by Formula 2, even more preferably an n-valent aliphatic group having 5 to 10 carbon atoms or a group represented by Formula 2, and particularly preferably a group represented by Formula 2, from viewpoints of tackiness, and bending resistance and hardness after curing.

In addition, A in Formula 1 is preferably an n-valent group consisting of a hydrogen atom and a carbon atom or an n-valent group consisting of a hydrogen atom, a carbon atom, and an oxygen atom, more preferably an n-valent group consisting of a hydrogen atom and a carbon atom, and particularly preferably an n-valent aliphatic hydrocarbon group, from viewpoints of tackiness, bending resistance and hardness after curing.

R¹'s in Formula 1 are each independently preferably an alkylene group having 1 to 15 carbon atoms, more preferably an alkylene group having 2 to 4 carbon atoms, even more preferably an alkylene group having 3 carbon atoms, and particularly preferably a 1,2-propylene group, from viewpoints of tackiness, bending resistance and hardness after curing. The alkylene group may be linear or branched.

R² to R⁴ in Formula 2 are each independently preferably an aliphatic group having 2 to 15 carbon atoms, more preferably an alkylene group having 2 to 15 carbon atoms or a polyalkyleneoxyalkyl group having 3 to 15 carbon atoms, even more preferably an alkylene group having 2 to 15 carbon atoms, and particularly preferably an ethylene group, from viewpoints of tackiness, and bending resistance and hardness after curing.

In addition, as the polyfunctional thiol compound, a compound having two or more groups represented by Formula S-1 is preferable.

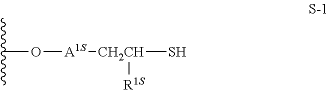

In Formula S-1, R^{1S} represents a hydrogen atom or an alkyl group, A^{1S} represents —CO— or —CH₂—, and wavy line parts represent bonding positions to another structure.

The polyfunctional thiol compound is preferably a compound having 2 to 6 groups represented by Formula S-1.

The alkyl group of R^{1S} in Formula S-1 is a linear, branched, or cyclic alkyl group, and a range of the number of carbon atoms is preferably 1 to 16 and more preferably 1 to 10. Specific examples of the alkyl group include a methyl group, an ethyl group, a propyl group, an isopropyl group, a butyl group, an isobutyl group, an s-butyl group, a t-butyl group, a pentyl group, a hexyl group, and a 2-ethylhexyl group, and a methyl group, an ethyl group, a propyl group, or an isopropyl group is preferable.

As R^{1S}, a hydrogen atom, a methyl group, an ethyl group, a propyl group, or an isopropyl group is particularly preferable, and a methyl group or an ethyl group is most preferable.

In addition, the polyfunctional thiol compound is particularly preferably a compound represented by Formula S-2 having a plurality of groups represented by Formula S-1.

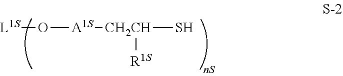

In Formula S-2, R^{1S}'s each independently represent a hydrogen atom or an alkyl group, A^{1S}'s each independently represent —CO— or —CH₂—, L^{1S} represents an nS-valent linking group, and nS represents an integer of 2 to 8. From a viewpoint of synthesis, it is preferable that all R^{1S}'s have the same group, and that all A^{1S}'s have the same group.

R^{1S} in Formula S-2 is same as R^{1S} in Formula S-1 and the preferred range is also the same. nS is preferably an integer of 2 to 6.

Examples of L^{1S}, which is an nS-valent linking group in Formula S-2, include a divalent linking group such as —(CH₂)—_{mS}— (mS represents an integer of 2 to 6), a trivalent linking group such as a trimethylolpropane residue, isocyanuric ring having three of —(CH₂)_{pS}-(pS represents an integer of 2 to 6), a tetravalent linking group such as a pentaerythritol residue, and a pentavalent or hexavalent linking group such as a dipentaerythritol residue.

Specific examples of the thiol compound preferably include the following compounds, but are not limited thereto.

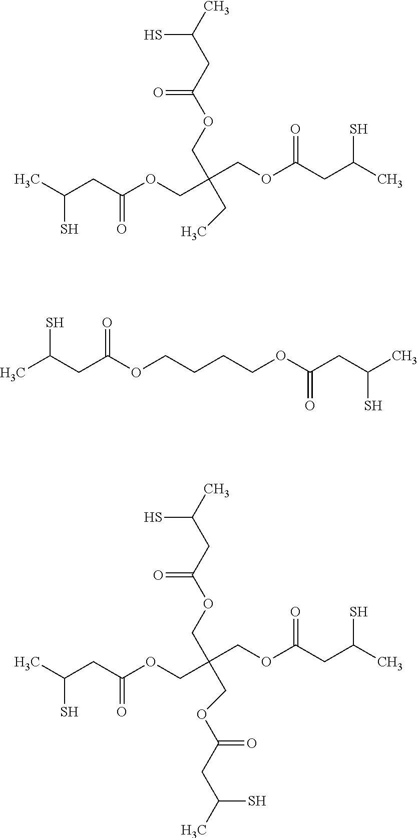

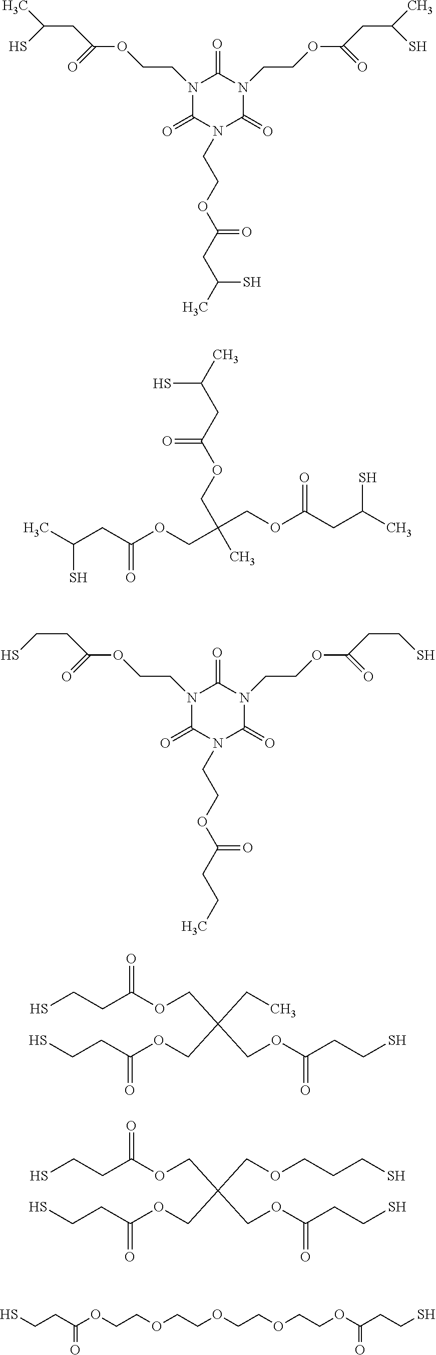

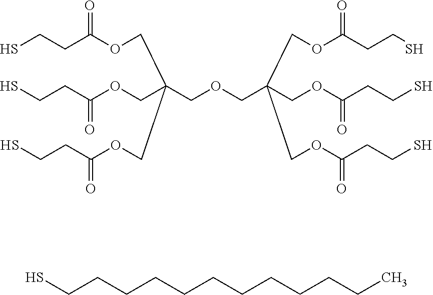 [SMILES: O=C(CCS)OCC(COCC(COC(=O)CCS)(COC(=O)CCS)COC(=O)CCS)(COC(=O)CCS)COC(=O)CCS ; CCCCCCCCCCCCS]

The thiol compounds may be used alone or in combination of two or more thereof.

The content of the thiol compound is preferably 1% by mass or more, more preferably 1% by mass to 40% by mass, even more preferably 3% by mass to 25% by mass, and particularly preferably 5% by mass to 15% by mass, with respect to the solid content amount of the photosensitive composition (or total mass of the photosensitive layer).

(Binder Polymer)

The photosensitive composition of the disclosure preferably contains a binder polymer.

The binder polymer is preferably an alkali soluble resin.

The binder polymer is not particularly limited, but from a viewpoint of developability, the binder polymer is preferably a binder polymer having an acid value of 60 mgKOH/g or more, more preferably an alkali soluble resin having an acid value of 60 mgKOH/g or more, and particularly preferably a carboxyl group-containing acrylic resin having an acid value of 60 mgKOH/g or more.

It is assumed that the binder polymer having an acid value can be thermally crosslinked with a compound capable of reacting with an acid by heating to increase a three-dimensional crosslink density. In addition, it is assumed that a carboxyl group of the carboxyl group-containing acrylic resin is dehydrated and made hydrophobic to contribute to improvement of wet heat resistance.

The carboxyl group-containing acrylic resin having an acid value of 60 mgKOH/g or more (hereinafter, may be referred to as a specific polymer A) is not particularly limited, as long as the acid value condition is satisfied, and a resin can be suitably selected and used from well-known resins.

For example, a binder polymer which is a carboxyl group-containing acrylic resin having an acid value of 60 mgKOH/g or more among polymers disclosed in paragraph 0025 of JP2011-095716A, a carboxyl group-containing acrylic resin having an acid value of 60 mgKOH/g or more among polymers disclosed in paragraphs 0033 to 0052 of JP2010-237589A, and the like can be preferably used as the specific polymer A in the embodiment.

Here, the (meth)acrylic resin indicates to a resin containing at least one of a constitutional unit derived from (meth)acrylic acid or a constitutional unit derived from a (meth)acrylic acid ester.

A total ratio of the constitutional unit derived from (meth)acrylic acid and the constitutional unit derived from (meth)acrylic acid ester in the (meth)acrylic resin is preferably 30 mol % or more and more preferably 50 mol % or more.

A range of a copolymerization ratio of the monomer having a carboxyl group in the specific polymer A is preferably 5% by mass to 50% by mass, more preferably 5% by mass to 40% by mass, and even more preferably 10% by mass to 30% by mass, with respect to 100% by mass of the specific polymer A.

The specific polymer A may have a reactive group, and as a method for introducing the reactive group into the specific polymer A, a method for causing a reaction of an epoxy compound, blocked isocyanate, isocyanate, a vinyl sulfone compound, an aldehyde compound, a methylol compound, a carboxylic acid anhydride, or the like with a hydroxyl group, a carboxyl group, a primary amino group, a secondary amino group, an acetoacetyl group, sulfonic acid, or the like is used.

Among these, the reactive group is preferably a radically polymerizable group, more preferably an ethylenically unsaturated group, and particularly preferably a (meth)acryloxy group.

In addition, the binder polymer, particularly the specific polymer A, preferably has a constitutional unit having an aromatic ring, from a viewpoint of moisture permeability and hardness after curing.

Examples of a monomer forming the constitutional unit having an aromatic ring include styrene, tert-butoxystyrene, methyl styrene, α-methyl styrene, and benzyl (meth)acrylate.

As the constitutional unit having an aromatic ring, it is preferable to contain at least one constitutional unit represented by Formula P-2 which will be described later. The constitutional unit having an aromatic ring is preferably a constitutional unit derived from a styrene compound.

In a case where the binder polymer includes a constitutional unit having an aromatic ring, a content of the constitutional unit having an aromatic ring is preferably 5% by mass to 90% by mass, and more preferably 10% by mass to 70% by mass, even more preferably 15% by mass to 50% by mass, with respect to a total mass of the binder polymer.

In addition, the binder polymer, particularly the specific polymer A, preferably has a constitutional unit having an alicyclic skeleton, from a viewpoint of tackiness and hardness after curing.

Specific examples of the monomer forming the constitutional unit having an alicyclic skeleton include dicyclopentanyl (meth)acrylate, cyclohexyl (meth)acrylate, and isobornyl (meth)acrylate.

Preferred examples of the aliphatic ring included in the constitutional unit having an alicyclic skeleton include a dicyclopentane ring, a cyclohexane ring, an isoborone ring, and a tricyclodecane ring. Among these, a tricyclodecane ring is particularly preferable.

In a case where the binder polymer includes a constitutional unit having an alicyclic skeleton, a ratio of the constitutional unit having an alicyclic skeleton is preferably 5% by mass to 90% by mass, more preferably 10% by mass to 80% by mass, and even more preferably 20% by mass to 70% by mass, with respect to a total mass of the binder polymer.

In addition, the binder polymer, particularly the specific polymer A, preferably has a constitutional unit having an ethylenically unsaturated group, from a viewpoint of tackiness and hardness after curing.

The ethylenically unsaturated group is preferably a (meth)acryl group and more preferably a (meth)acryloxy group.

In a case where the binder polymer includes a constitutional unit having an ethylenically unsaturated group, a ratio of the constitutional unit having an ethylenically unsaturated group is preferably 5% by mass to 70% by mass, and more preferably 5% by mass to 50% by mass, even more preferably 10% by mass to 40% by mass, with respect to a total mass of the binder polymer.

The acid value of the binder polymer is preferably 60 mgKOH/g to 200 mgKOH/g, more preferably 60 mgKOH/g to 150 mgKOH/g, and even more preferably 60 mgKOH/g to 130 mgKOH/g.

The acid value refers to a value measured according to the method disclosed in JIS K0070 (1992).

In a case where the binder polymer contains a binder polymer having an acid value of 60 mgKOH/g or more, the adhesiveness with the oxide particle-containing layer can be increased.

A weight-average molecular weight of the specific polymer A is preferably 5,000 or more and more preferably 10,000 to 100,000.

In addition, as the binder polymer, any film-forming resin can be suitably selected and used according to the purpose, in addition to the specific polymer. From a viewpoint of using the photosensitive layer as the protective film of electrode or the like in the capacitive input device, a film having excellent surface hardness and heat resistance is preferable, and accordingly, an alkali soluble resin is more preferable and a well-known photosensitive siloxane resin material can be preferably used as the binder polymer.

The binder polymer preferably includes a polymer containing a constitutional unit having a carboxylic acid anhydride structure (hereinafter, also referred to as a specific polymer B). By including the specific polymer B, the developability and the hardness after curing are more excellent.

The carboxylic acid anhydride structure may be either a chain-like carboxylic acid anhydride structure or a cyclic carboxylic acid anhydride structure, and is preferably a cyclic carboxylic acid anhydride structure.

The ring of the cyclic carboxylic acid anhydride structure is preferably a 5- to 7-membered ring, more preferably a 5-membered ring or a 6-membered ring, and even more preferably a 5-membered ring.

In addition, the cyclic carboxylic acid anhydride structure may be condensed or bonded with another ring structure to form a polycyclic structure, but preferably does not form a polycyclic structure.

In a case where another ring structure is condensed or bonded to the cyclic carboxylic acid anhydride structure to form a polycyclic structure, the polycyclic structure is preferably a bicyclo structure or a spiro structure.

In the polycyclic structure, the number of other ring structures condensed or bonded to the cyclic carboxylic acid anhydride structure is preferably 1 to 5, and more preferably 1 to 3.

Examples of the other ring structure include a cyclic hydrocarbon group having 3 to 20 carbon atoms and a heterocyclic group having 3 to 20 carbon atoms.

The heterocyclic group is not particularly limited, and examples thereof include an aliphatic heterocyclic group and an aromatic heterocyclic group.

In addition, the heterocyclic group is preferably a 5-membered ring or a 6-membered ring, and particularly preferably a 5-membered ring.

Further, as the heterocyclic group, a heterocyclic group containing at least one oxygen atom (for example, an oxolane ring, an oxane ring, or a dioxane ring) is preferable.

The constitutional unit having a carboxylic acid anhydride structure is preferably a constitutional unit containing a divalent group obtained by removing two hydrogen atoms from a compound represented by Formula P-1 in a main chain, or a constitutional unit in which a monovalent group obtained by removing one hydrogen atom from a compound represented by Formula P-1 is bonded to the main chain directly or via a divalent linking group.

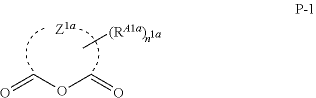

In Formula P-1, R^{A1a} represents a substituent and n^{1a} R^{A1a}'s maybe the same or different. Z^{1a} represents a divalent group forming a ring containing —C(═O)—O—C(═O)—. n^{1a} represents an integer of 0 or more.

As a substituent represented by R^{A1a},the same substituent as the substituent which may be included in the carboxylic acid anhydride structure may be used, and the preferable range is also the same.

Z^{1a} is preferably an alkylene group having 2 to 4 carbon atoms, more preferably an alkylene group having 2 or 3 carbon atoms, and particularly preferably an alkylene group having 2 carbon atoms.

In addition, the partial structure represented by Formula P-1 may be condensed or bonded with another ring structure to form a polycyclic structure, but preferably does not form a polycyclic structure.

As the other ring structure here, the same ring structure as the other ring structure described above which may be condensed or bonded to the carboxylic acid anhydride structure may be used, and the preferable range is also the same.

n^{1a} represents an integer of 0 or more.

In a case where Z^{1a} represents an alkylene group having 2 to 4 carbon atoms, n^{1a} is preferably an integer of 0 to 4, more preferably an integer of 0 to 2, and even more preferably 0.

In a case where n^{1a} represents an integer of 2 or more, a plurality of R^{A1a}'s existing may be the same or different. In addition, the plurality of R^{A1a}'s existing may be bonded to each other to form a ring, but it is preferable that they are not bonded to each other to form a ring.

The constitutional unit having a carboxylic acid anhydride structure is preferably a constitutional unit derived from an unsaturated carboxylic acid anhydride, more preferably a constitutional unit derived from an unsaturated cyclic carboxylic acid anhydride, even more preferably a constitutional unit derived from an unsaturated alicyclic carboxylic acid anhydride, still preferably a constitutional unit derived from maleic acid anhydride or itaconic acid anhydride, and particularly preferably a constitutional unit derived from maleic acid anhydride.

Hereinafter, specific examples of the constitutional unit having a carboxylic acid anhydride structure will be described, but the constitutional unit having a carboxylic acid anhydride structure is not limited to these specific examples.

In the following constitutional units, Rx represents a hydrogen atom, a methyl group, a CH₂OH group, or a CF₃ group, and Me represents a methyl group.

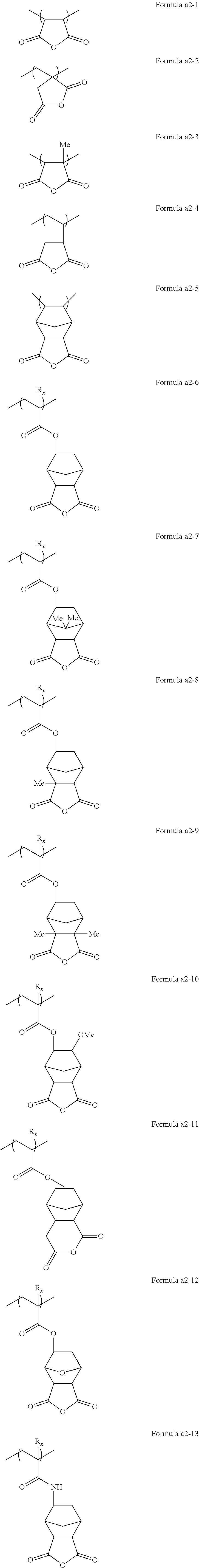

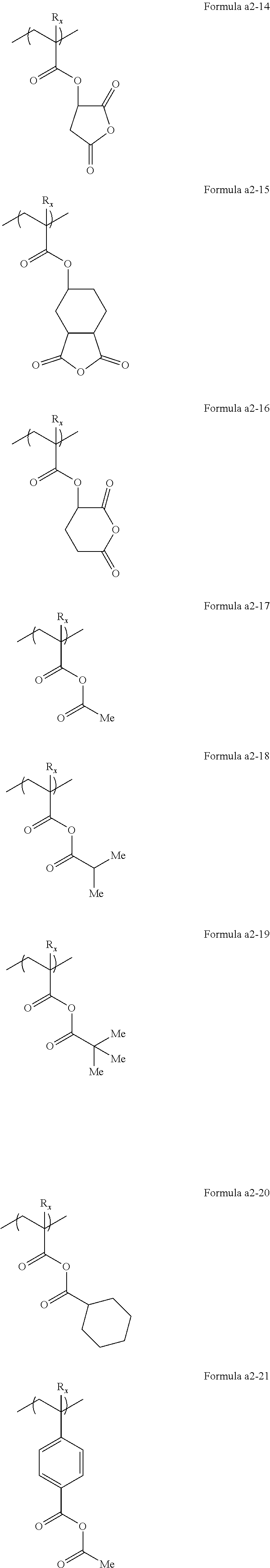

The constitutional unit having a carboxylic acid anhydride structure is preferably at least one of the constitutional units represented by any of Formulae a2-1 to a2-21, and more preferably one of the constitutional units represented by any of Formulae a2-1 to a2-21.

The constitutional unit having a carboxylic acid anhydride structure preferably has at least one of the constitutional unit represented by Formula a2-1 or the constitutional unit represented by Formula a2-2, and more preferably the constitutional unit represented by Formula a2-1, from viewpoints of improving perspiration resistance of the cured layer and reducing the development residue in a case where the photosensitive transfer material is used.

A content of constitutional unit having a carboxylic acid anhydride structure in the specific polymer B (in the case of two or more kinds, total content thereof. The same applies hereinafter) is preferably 0 mol % to 60 mol %, more preferably 5 mol % to 40 mol %, and even more preferably 10 mol % to 35 mol %, with respect to the total amount of the specific polymer B.

In the disclosure, in a case where the content of the “constitutional unit” is defined by a molar ratio, the “constitutional unit” is synonymous with the “monomer unit”. In addition, the “monomer unit” may be modified after polymerization by a polymer reaction or the like. The same applies to the followings.

As the specific polymer B, it is preferable to contain at least one constitutional unit represented by Formula P-2. This further improves hydrophobicity and hardness of the cured layer that is formed.

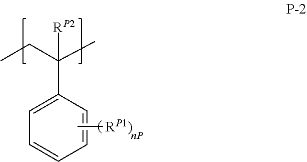

In Formula P-2, R^{P1} represents a hydroxyl group, an alkyl group, an aryl group, an alkoxy group, a carboxy group, or a halogen atom, R^{P2} represents a hydrogen atom, an alkyl group, or an aryl group, and nP represents an integer of 0 to 5. In a case where nP is an integer of 2 or more, two or more existing R^{P1}'s may be the same or different.

R^{P1} is preferably an alkyl group having 1 to 10 carbon atoms, an aryl group having 6 to 12 carbon atoms, an alkoxy group having 1 to 10 carbon atoms, a carboxy group, an F atom, a Cl atom, a Br atom, or an I atom, and more preferably an alkyl group having 1 to 4 carbon atoms, a phenyl group, an alkoxy group having 1 to 4 carbon atoms, a Cl atom, or a Br atom.

R^{P2} is preferably a hydrogen atom, an alkyl group having 1 to 10 carbon atoms, or an aryl group having 6 to 12 carbon atoms, more preferably a hydrogen atom or an alkyl group having 1 to 4 carbon atoms, even more preferably a hydrogen atom, a methyl group, or an ethyl group, and particularly preferably a hydrogen atom.

nP is preferably an integer of 0 to 3, more preferably 0 or 1, and further preferably 0.

A constitutional unit represented by Formula P-2 is preferably a constitutional unit derived from a styrene compound.

Examples of the styrene compound include styrene, p-methylstyrene, α-methylstyrene, α, p-dimethylstyrene, p-ethylstyrene, p-t-butylstyrene, and 1,1-diphenylethylene, styrene or a-methylstyrene is preferable, and styrene is particularly preferable.

The styrene compound for forming the constitutional unit represented by Formula P-2 may be only one or two or more kinds thereof.

In a case where the specific polymer B includes the constitutional unit represented by Formula P-2, a content of the constitutional units represented by Formula P-2 in the specific polymer B (in the case of two or more kinds, total content thereof. The same applies hereinafter) is preferably 5 mol % to 90 mol %, more preferably 30 mol % to 90 mol %, and even more preferably 40 mol % to 90 mol %, with respect to the total amount of the specific polymer B.

The specific polymer B may include at least one constitutional unit other than the constitutional unit having a carboxylic acid anhydride structure and the constitutional unit represented by Formula P-2.

The other constitutional unit preferably does not contain an acid group.

The other constitutional unit is not particularly limited, and a constitutional unit derived from a monofunctional ethylenically unsaturated compound is used.

As the monofunctional ethylenically unsaturated compound, well-known compounds can be used without particular limitation, and examples thereof include a (meth)acrylic acid derivative such as methyl (meth)acrylate, ethyl (meth)acrylate, n-butyl (meth)acrylate, 2-ethylhexyl (meth)acrylate, carbitol (meth)acrylate, cyclohexyl (meth)acrylate, benzyl (meth)acrylate, or epoxy (meth)acrylate; an N-vinyl compound such as N-vinylpyrrolidone or N-vinylcaprolactam; and a derivative of an allyl compound such as allyl glycidyl ether.

A content of the other constitutional units in the specific polymer B (in the case of two or more kinds, total content thereof) is preferably 0 mol % to 90 mol %, and more preferably 0 mol % to 70 mol %, with respect to the total amount of the specific polymer B.

A weight-average molecular weight of the binder polymer is not particularly limited, and is preferably more than 3,000, more preferably more than 3,000 and 60,000 or less, and even more preferably 5,000 to 50,000.

The binder polymer may be used alone or in combination of two or more kinds thereof.

A content of the binder polymer is preferably 10% by mass to 90% by mass, more preferably 20% by mass to 80% by mass, and even more preferably 30% by mass to 70% by mass, with respect to the solid content amount of the photosensitive composition (or total mass of the photosensitive layer), from a viewpoint of the photosensitivity and the hardness of the cured layer.

(Solvent)

In the formation of the photosensitive layer, the photosensitive composition may contain at least one kind of solvent, from a viewpoint of forming the photosensitive layer by coating.

As the solvent, a solvent normally used can be used without particular limitations.

The solvent is preferably an organic solvent.

Examples of the organic solvent include methyl ethyl ketone, propylene glycol monomethyl ether, propylene glycol monomethyl ether acetate (another name: 1-methoxy-2-propyl acetate), diethylene glycol ethyl methyl ether, cyclohexanone, methyl isobutyl ketone, ethyl lactate, methyl lactate, caprolactam, n-propanol, and 2-propanol. In addition, the solvent used may include a mixed solvent which is a mixture of these compounds.

As the solvent, a mixed solvent of methyl ethyl ketone and propylene glycol monomethyl ether acetate, or a mixed solvent of diethylene glycol ethyl methyl ether and propylene glycol monomethyl ether acetate is preferably used.

In a case of using the solvent, a solid content amount of the photosensitive composition is preferably 5% by mass to 80% by mass, more preferably 5% by mass to 40% by mass, and particularly preferably 5% by mass to 30% by mass with respect to a total amount of the photosensitive composition.

In a case of using the solvent, a viscosity (25° C.) of the photosensitive composition is preferably 1 mPa·s to 50 mPa·s, more preferably 2 mPa·s to 40 mPa·s, and particularly preferably 3 mPa·s to 30 mPa·s, from a viewpoint of coating properties.

The viscosity is, for example, measured using VISCOMETER TV-22 (manufactured by Toki Sangyo Co. Ltd.).

In a case where the photosensitive composition includes the solvent, a surface tension (25° C.) of the photosensitive composition is preferably 5 mN/m to 100 mN/m, more preferably 10 mN/m to 80 mN/m, and particularly preferably 15 mN/m to 40 mN/m, from a viewpoint of coating properties.

The surface tension is, for example, measured using Automatic Surface Tensiometer CBVP-Z (manufactured by Kyowa Interface Science Co., Ltd.).

As the solvent, a solvent disclosed in paragraphs 0054 and 0055 of US2005/282073A can also be used, and the content of this specification is incorporated in the present specification.

In addition, as the solvent, an organic solvent (high-boiling-point solvent) having a boiling point of 180° C. to 250° C. can also be used, as necessary.

(Other Components)

The photosensitive composition may include a component other than the components described above.

Examples of the other components include a surfactant, a polymerization inhibitor, a thermal polymerization inhibitor disclosed in paragraph 0018 of JP4502784B, and other additives disclosed in paragraphs 0058 to 0071 of JP2000-310706A.

Surfactant

As the surfactant, for example, surfactants disclosed in paragraph 0017 of JP4502784B and paragraphs 0060 to 0071 of JP2009-237362A, well-known fluorine-based surfactants, and the like can be used. As the surfactant, a fluorine-based surfactant is preferable. As a commercially available fluorine-based surfactant, MEGAFACE (registered trademark) F551 (manufactured by DIC Corporation) is used.

In a case where the photosensitive composition (or photosensitive layer) includes a surfactant, a content of the surfactant is preferably 0.01% by mass to 3% by mass, more preferably 0.05% by mass to 1% by mass, and even more preferably 0.1% by mass to 0.8% by mass, with respect to the solid content amount of the photosensitive composition (or total mass of the photosensitive layer).

Polymerization Inhibitor

As the polymerization inhibitor, for example, a thermal polymerization inhibitor (also referred to as a polymerization inhibitor) disclosed in paragraph 0018 of JP4502784B can be used. Among them, phenothiazine, phenoxazine, or 4-methoxyphenol can be preferably used.

In a case where the photosensitive composition (or photosensitive layer) includes a polymerization inhibitor, a content of the polymerization inhibitor is preferably 0.01% by mass to 3% by mass, more preferably 0.01% by mass to 1% by mass, and even more preferably 0.01% by mass to 0.8% by mass, with respect to the solid content amount of the photosensitive composition (or total mass of the photosensitive layer).

Hydrogen Donating Compound

The hydrogen donating compound has a function of further improving the sensitivity of the photopolymerization initiator to active light, or suppressing inhibition of polymerization of the polymerizable compound by oxygen.

Examples of such a hydrogen donating compound include amines, for example, M. R. Sander et al., “Journal of Polymer Society,” Vol. 10, page 3173 (1972), JP1969-020189B (JP-S44-020189B), JP1976-082102A (JP-S51-082102A), JP1977-134692A (JP-S52-134692A), JP1984-138205A (JP-S59-138205A), JP1985-084305A (JP-S60-084305A), JP1987-018537A (JP-S62-018537), JP1989-033104A (JP-S64-033104A), and Research Disclosure 33825, and specific examples thereof include triethanolamine, p-dimethylaminobenzoic acid ethyl ester, p-formyldimethylaniline, and p-methylthiodimethylaniline.

In addition, other examples of the hydrogen donating compound further include an amino acid compound (for example, N-phenylglycine or the like), an organic metal compound disclosed in JP1973-042965B (JP-S48-042965B) (for example, tributyltin acetate, or the like), a hydrogen donor disclosed in JP1980-034414B (JP-S55-034414B), and a sulfur compound disclosed in JP1994-308727A (JP-H6-308727A) (for example, trithiane or the like).

A content of the hydrogen donating compounds is preferably in a range of 0.1% by mass to 30% by mass, more preferably in a range of 0.1% by mass to 25% by mass, and even more preferably in a range of 0.5% by mass to 20% by mass, with respect to solid content amount of the photosensitive composition (or total mass of the photosensitive layer), from a viewpoint of improving a curing speed with balance between a polymerization growth speed and chain transfer.

Particles

Examples of the particles include metal oxide particles other than a titanium oxide particle and a zirconium oxide particle, and the metal of the metal oxide particles also include metalloids such as B, Si, Ge, As, Sb, and Te. Other metal oxide particles can adjust the refractive index and light transmittance, and can be contained within a range that does not significantly impair the effects of the disclosure.

From a viewpoint of the transparency of the cured layer, an average primary particle diameter of the particles is preferably 1 nm to 200 nm and more preferably 3 nm to 80 nm. The average primary particle diameter is calculated by measuring particle diameters of 200 random particles using an electron microscope and arithmetically averaging the measured result. In a case where the shape of the particle is not a spherical shape, the longest side is set as the particle diameter.

Colorant

A Colorant includes a pigment, a dye, and the like. The colorant can be used within the range that does not impair the effects of the disclosure, but from a viewpoint of transparency, it is preferable that the colorant is not substantially contained. Specifically, a content of the colorant is preferably smaller than 1% by mass and more preferably smaller than 0.1% by mass with respect to the solid content amount of the photosensitive composition (or total mass of the photosensitive layer).

<Capacitive Input Device>

The capacitive input device of the disclosure comprises the laminate described above.

As the capacitive input device, a touch panel is suitably used.

As the electrode for a touch panel disposed on a touch panel, a transparent electrode pattern disposed at least in an image display region of the touch panel is used. The electrode for a touch panel may extend from the image display region to a frame portion of the touch panel.

As the wiring for a touch panel disposed on the touch panel, the leading wiring (lead-out wiring) disposed on the frame portion of the touch panel is used, for example.

As a preferred embodiment of the base material for a touch panel used in the touch panel and the touch panel, an embodiment in which the transparent electrode pattern and the leading wiring are electrically connected to each other by laminating a part of the leading wiring on a portion of the transparent electrode pattern extending to the frame portion of the touch panel, is suitable.

As a material of the transparent electrode pattern, a metal oxide film of indium tin oxide (ITO) and indium zinc oxide (IZO) is preferable.

As a material of the leading wiring, metal is preferable. Examples of the metal which is the material of the leading wiring include gold, silver, copper, molybdenum, aluminum, titanium, chromium, zinc, and manganese, and alloy consisting of two or more kinds of these metal elements. As the material of the leading wiring, copper, molybdenum, aluminum, or titanium is preferable, copper is particularly preferable.

The laminate according to the disclosure can be provided so as to cover the electrode and the like as a material which protects the electrode and the like (that is, at least one of the electrode for a touch panel or the wiring for a touch panel) (preferably electrode protective film for a touch panel). The laminate of the disclosure may have an opening. The opening can be formed by dissolving an unexposed portion of the photosensitive layer with a developer.

In the case of a touch panel, another refractive index adjusting layer may be further comprised between the laminate of the disclosure and the electrodes or the like. The preferred embodiment of the other refractive index adjusting layer is the same as the preferred embodiment of the oxide particle-containing layer of the disclosure. The other refractive index adjusting layer may be formed by applying and drying a composition for forming the refractive index adjusting layer, or may be formed by transferring the refractive index adjusting layer of the photosensitive transfer material comprising the refractive index adjusting layer.

The touch panel or the base material for a touch panel may comprise the refractive index adjusting layer between the substrate and the electrode and the like. The preferred embodiment of the refractive index adjusting layer is the same as the preferred embodiment of the resin layer of the disclosure.

Regarding the structure of the touch panel, a structure of a capacitive input device disclosed in JP2014-010814A or JP2014-108541A may be referred to. Examples

Hereinafter, embodiments of the invention will be specifically described with reference to specific examples. However, the embodiment of the invention is not limited to the following examples as long as the gist of the present invention is not exceeded, and the materials, the amount used, the ratio, the process contents, the process procedure, and the like shown in the following examples can be suitably changed, within a range not departing from a gist of the disclosure.

“part” is based on mass, unless otherwise noted.

In addition, in the following examples, a weight-average molecular weight of a resin is a weight-average molecular weight obtained by performing polystyrene conversion of a value measured by gel permeation chromatography (GPC). Further, a theoretical acid value was used for the acid value.

<Synthesis of Polymer>

First, polymers P-1 and P-2 were synthesized as resins contained in the photosensitive composition (or resin layer).

(Synthesis of Polymer P-1)

244.2 parts by mass of propylene glycol monomethyl ether (MFG manufactured by FUJIFILM Wako Pure Chemical Corporation) was placed in a three-neck flask and kept at 90° C. under nitrogen. A mixed solution of 120.4 parts by mass of dicyclopentanyl methacrylate (manufactured by Tokyo Chemical Industry Co., Ltd.), 96.1 parts by mass of methacrylic acid (MAA, manufactured by FUJIFILM Wako Pure Chemical Corporation), 87.2 parts by mass of styrene (manufactured by FUJIFILM Wako Pure Chemical Corporation), 188.5 parts by mass of MFG 0.0610 parts by mass of p-methoxyphenol (manufactured by FUJIFILM Wako Pure Chemical Corporation), and 16.7 parts by mass of V-601 (dimethyl-2,2′-azobis (2-methylpropionate), manufactured by FUJIFILM Wako Pure Chemical Corporation) was added dropwise thereto for 3 hours.

After the dropwise addition, the mixed solution was stirred at 90° C. for 1 hour, and the mixed solution of V-601 (2.1 parts by mass) and MFG (5.2 parts by mass) was added and stirred for 1 hour. Then, the mixed solution of V-601 (2.1 parts by mass) and MFG (5.2 g parts by mass) was further added. After stirring for 1 hour, the mixed solution of V-601 (2.1 parts by mass) and MFG (5.2 parts by mass) was further added. After stirring for 3 hours, 2.9 parts by mass of MFG and 166.9 parts by mass of propylene glycol monomethyl ether acetate (PGMEA, manufactured by Daicel Chemical Co., Ltd.) were added and stirred until it is uniform.

1.5 parts by mass of tetramethylammonium bromide (TEAB, manufactured by Tokyo Chemical Industry Co., Ltd.) and 0.7 parts by mass of p-methoxyphenol were added to a reaction liquid as addition catalysts, and the temperature was raised to 100° C. In addition, 62.8 parts by mass of glycidyl methacrylate (GMA, manufactured by FUJIFILM Wako Pure Chemical Corporation) was added and stirred at 100° C. for 9 hours to obtain an MFG/PGMEA mixed solution of the polymer P-1.

A weight-average molecular weight of the polymer P-1 measured by GPC was 20,000 (in terms of polystyrene), and a polymer concentration (concentration of solid contents) in the polymer solution was 36.3% by mass.

(Synthesis of Polymer P-2)

The following polymer P-2 was synthesized in the same manner as in the synthesis of the polymer P-1 to obtain an MFG/PGMEA mixed solution of the polymer P-2.

A weight-average molecular weight of the polymer P-2 measured by GPC was 29,000 (in terms of polystyrene), and a polymer concentration (concentration of solid contents) in the polymer solution was 36.3% by mass.

The polymers P-1 and P-2 are shown below. A ratio of each constitutional unit in the formula is the mass ratio. Me represents a methyl group.

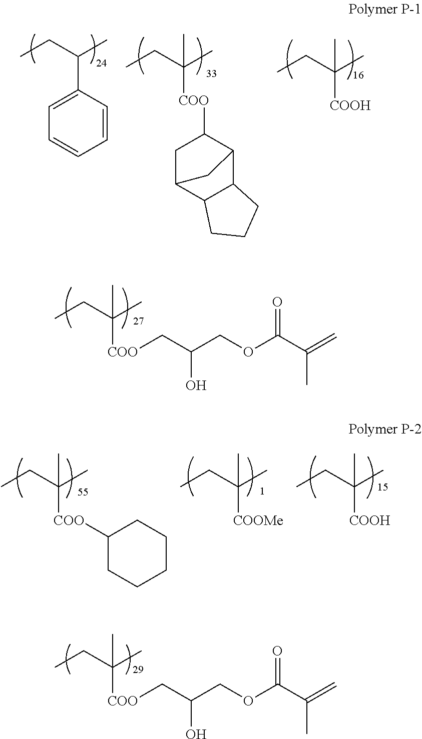

<Preparation of Photosensitive Composition for Forming Resin Layer 1>

Each component in the composition shown in Table 1 was mixed to prepare photosensitive compositions A-1 to A-5. The amount of the polymer in Table 1 means the amount of the polymer solution (polymer concentration: 36.3% by mass).

TABLE 1

| | Photosensitive composition | | | | |
|---|---|---|---|---|---|
| | A-1 | A-2 | A-3 | A-4 | A-5 |
| Radically polymerizable compound | | | | | |
| Tricyclodecane dimethanol diacrylate | 1.84 | 3.52 | 4.04 | 0.44 | 1.73 |
| (A-DCP, manufactured by Shin-Nakamura Chemical Co., Ltd.) | | | | | |
| Urethane actylate compound include 8UX-015A | — | 1.76 | 2.02 | 0.22 | 0.86 |
| (manufactured by Taisei Fine Chemical Co., Ltd.) | | | | | |
| Carboxylic group-containing monomer ARONIX TO-2349 | 0.46 | 0.59 | 0.67 | 0.07 | 0.29 |
| (manufactured by TOAGOSEI CO., LTD) | | | | | |
| Polytetramethylene glycol diacrylate | — | — | — | — | — |
| (A-PTMG-65, manufactured by Shin-Nakamura Chemical Co., Ltd) | | | | | |
| Polypropylene glycol diacrylate | — | — | — | — | — |
| (APG-700, manufactured by Shin-Nakamura Chemical Co., Ltd.) | | | | | |
| Polymer | | | | | |
| P-1 | — | — | — | — | — |
| P-2 | 21.12 | 17.95 | 15.47 | 1.68 | 26.45 |
| Photopoly merization initiator | | | | | |
| 1-[9-ethyl-6-(2-methylbenzoy1)-9H-carbazol-3-yl]ethanone-1-(O-acetyl | 0.26 | 0.07 | 0.08 | 0.01 | 0.03 |
| oxime) (OXE-02, manufactured by BASF Japan Ltd.) | | | | | |
| 2-methyl-1-(4-methylthiophenyl)-2-morpholinopropan-1-one | 0.05 | 0.13 | 0.15 | 0.02 | 0.07 |
| (IRGACURE 907, manufactured by BASF Japan Ltd.) | | | | | |
| Blocked isocyanate compound | | | | | |
| Karenz AOI-BM (manufactured by SHOWA DENKO K.K. , | — | — | — | — | — |
| photopolymerizable blocked isocyanate) | | | | | |
| DURANATE TPA-B80E | 2.42 | 2.42 | 2.42 | 0.50 | 2.42 |
| (manufactured by Asahi Kasei Chemicals Corporation) | | | | | |
| Thiol compound | | | | | |
| trimethylolpropane tris (3-mercaptobutyrate) | — | — | — | — | — |
| (TPMB, manufactured by SHOWA DENKO K.K.) | | | | | |
| 1,4-bis (3-mercaptobutyryloxy) butane | 2.30 | — | — | — | — |
| (Karenz MT-BD1, manufactured by SHOWA DENKO K.K.) | | | | | |
| Other components | | | | | |
| N-phenylglycine (manufactured by JUNSEI CHEMICAL CO., LTD.) | 0.01 | 0.01 | 0.01 | 0.00 | 0.01 |
| 1,2,4-triazole (manufactured by Otsuka Chemical Co., Ltd.) | — | — | — | — | — |
| Benzimidazole (manufactured by Tokyo Chemical Industry Co., Ltd.) | 0.04 | 0.04 | 0.04 | 0.01 | 0.04 |
| SMA EF-40 (manufactured by Cray valley) | — | — | — | — | — |
| MEGAFACE F551A (manufactured by DIC CORPORATION) | 0.16 | 0.16 | 0.16 | 0.16 | 0.16 |
| ZR-010 (manufactured by SOLAR CO., LTD.) | — | — | — | 4.00 | -— |
| Solvent | | | | | |
| Methyl ethyl ketone | 71.33 | 73.35 | 74.94 | 92.90 | 67.94 |
| Drying thickness [μm] | 0.50 | 0.50 | 0.50 | 0.50 | 0.10 |

<Preparation of Photosensitive Composition for Forming Resin Layer 2>

Each component in the composition shown in Table 2 was mixed to prepare photosensitive compositions B-1 to B-8. The amount of the polymer in Table 2 means the amount of the polymer solution (polymer concentration: 36.3% by mass).

TABLE 2

| | Photosensitive composition | | | | | | | |
|---|---|---|---|---|---|---|---|---|
| | B-1 | B-2 | B-3 | B-4 | B-5 | B-6 | B-7 | B-8 |
| Radically polymerizable compound | | | | | | | | |
| Tricyclodecane dimethanol diaciylate | 5.53 | 5.53 | 3.73 | — | — | 3.42 | 2.48 | 5.53 |
| (A-DCP, manufactured by Shin-Nakamura Chemical Co., | | | | | | | | |
| Ltd.) | | | | | | | | |
| Urethane acrylate compound include 8UX-015A | — | — | — | — | — | 1.71 | 1.24 | 2.76 |
| (manufactured by Taisei Fine Chemical Co., Ltd.) | | | | | | | | |
| Carboxylic group-containing monomer ARONIX | 0.92 | 0.92 | 0.93 | — | — | 0.57 | 0.41 | 0.92 |
| TO-2349 | | | | | | | | |
| (manufactured by TOAGOSEI CO., LTD) | | | | | | | | |
| Polytetramethylene glycol diaciylate | — | — | — | 9.33 | — | — | — | — |
| (A-PTMG-65, manufactured by Shin-Nakamura | | | | | | | | |
| Chemical Co., Ltd) | | | | | | | | |
| Polypropylene glycol diaciylate | — | — | — | — | 9.33 | — | — | — |
| (APG-700, manufactured by Shin-Nakamura Chemical | | | | | | | | |
| Co., Ltd.) | | | | | | | | |
| Polymer | | | | | | | | |
| P-1 | 42.31 | 42.31 | — | — | — | 52.33 | 56.82 | 42.31 |
| P-2 | — | — | 42.86 | 42.86 | 42.86 | — | — | 0.00 |
| Photopolymerization initiator | | | | | | | | |
| 1-[9-ethyl-6-(2-methylbenzoyl)-9H-carbazol-3-yl] ethano | 0.11 | 0.11 | 0.11 | 0.11 | 0.11 | 0.07 | 0.05 | 0.11 |
| ne-1-(O-acetyloxime) (OXE-02, manufactured by BASF | | | | | | | | |
| Japan Ltd.) | | | | | | | | |
| 2-methyl-1-(4-methylthiophenyl)-2-molpholinopropan-1- | 0.21 | 0.21 | 0.21 | 0.21 | 0.21 | 0.13 | 0.09 | 0.21 |
| one (IRGACURE 907, manufactured by BASF Japan | | | | | | | | |
| Ltd.) | | | | | | | | |
| Blocked isocyanate compound | | | | | | | | |
| Karenz AOI-BM (manufactured by SHOWA DENKO | 3.63 | 3.63 | — | — | — | 3.63 | 3.63 | 3.63 |
| K.K., photopolymerizable blocked isocyanate) | | | | | | | | |
| DURANATE TPA-B80E | — | — | 4.83 | 4.83 | 4.83 | | | — |
| (manufactured by Asahi Kasei Chemicals Corporation) | | | | | | | | |
| Thiol compound | | | | | | | | |
| trimethylolpropane tris (3-mercaptobutyrate) | 2.76 | — | — | — | — | — | — | — |
| (TPMB, manufactured by SHOWA DENKO K.K.) | | | | | | | | |
| 1,4-bis (3-mercaptobutyryloxy) butane | — | 2.76 | 4.67 | — | — | — | — | — |
| (Karenz MT-BD1, manufactured by SHOWA DENKO | | | | | | | | |
| K.K.) | | | | | | | | |
| Other components | | | | | | | | |
| N-phenylglycine (manufactured by JUNSEI CHEMICAL | 0.03 | 0.03 | 0.03 | 0.03 | 0.03 | 0.03 | 0.03 | 0.03 |
| CO., LTD.) | | | | | | | | |
| 1,2,4-triazole (manufactured by Otsuka Chemical Co., | 0.06 | 0.06 | — | — | — | 0.06 | 0.06 | 0.06 |
| Ltd.) | | | | | | | | |
| Benzimidazole (manufactured by Tokyo Chemical | — | — | 0.09 | 0.09 | 0.09 | — | — | 0.00 |
| Industry Co., Ltd.) | | | | | | | | |
| SMA EF-40 (manufactured by Cray valley) | 0.35 | 0.35 | — | — | — | 0.35 | 0.35 | 0.35 |
| MEGAFACE F551A (manufactured by DIC | 0.16 | 0.16 | 0.16 | 0.16 | 0.16 | 0.16 | 0.16 | 0.16 |
| CORPORATION) | | | | | | | | |
| ZR-010 (manufactured by SOLAR CO., LTD.) | — | — | — | — | — | — | — | — |
| Solvent | | | | | | | | |
| Methyl ethyl ketone | 43.94 | 43.94 | 42.38 | 42.38 | 42.38 | 37.55 | 34.69 | 43.94 |
| Drying thickness [μm] | 8.30 | 8.30 | 8.30 | 8.30 | 8.30 | 8.30 | 8.30 | 8.30 |

<Manufacturing of Transfer Film>

Next, the transfer film was manufactured as described below.

### Transfer Films A-1 to A-5

5 temporary supports (Lumirer 16QS62 (thickness of 16 μm), manufactured by Toray Industries, Inc.; polyethylene terephthalate film) were prepared, any of photosensitive compositions A-1 to A-5 were respectively applied onto temporary supports using a slit-shaped nozzle and dried to form a photosensitive layer 1 having a drying thickness shown in Table 1. Next, protective films (Trefan 12KW37 (thickness: 12 μm), manufactured by Toray Industries, Inc.; polypropylene film) were respectively pressure-bonded onto the formed photosensitive layer 1 to manufacture transfer films A-1 to A-5.

Transfer Films B-1 to B-8-8 temporary supports (Lumirer 16QS62 (thickness of 16 μm), manufactured by Toray Industries, Inc.; polyethylene terephthalate film) were prepared, any of photosensitive compositions B-1 to B-8 were respectively applied onto temporary supports using a slit-shaped nozzle and dried to form a photosensitive layer 2 having a drying thickness shown in Table 2. Next, protective films (Trefan 12KW37 (thickness: 12 μm), manufactured by Toray Industries, Inc.; polypropylene film) were respectively pressure-bonded onto the formed photosensitive layer 2 to manufacture transfer films B-1 to B-8.

<Preparation of Substrate Used for Manufacturing of Laminate>

Manufacturing of Transparent Film Substrate 1

A cycloolefin resin film (COP film) having a film thickness of 38 μm and a refractive index of 1.53 was subjected to a corona discharge treatment for 3 seconds under the conditions of an electrode length of 240 mm, a distance between work electrodes of 1.5 mm at an output voltage of 100% and an output of 250 W with a wire electrode having a diameter of 1.2 mm by using a high frequency oscillator, to obtain a transparent film substrate subjected to surface reforming.

Next, a coating liquid containing the component of a material-C shown in Table 3 was applied onto a transparent film substrate using a slit-shaped nozzle, then irradiated with ultraviolet rays (integrated light amount of 300 mJ/cm²), and dried at approximately 110° C. to manufacture a transparent film having a refractive index of 1.60 and a film thickness of 80 nm.

By doing so, a transparent film substrate 1 including a transparent film was obtained.

The numerical value at the lower right part in Formula (3) is based on the mass.

TABLE 3

| Material | Material-C |
|---|---|
| ZrO₂: manufactured by SOLAR CO., LTD. ZR-010 | 2.08 |
| DPHA solution (dipentaerythritol hexa-acrylate: 38%, dipentaerythritol penta-acrylate: | 0.29 |
| 38%, 1-methoxy-2-propyl acetate: 24%) | |
| Urethane-based monomer: UK Oligo UA-32P manufactured by Shin-Nakamura Chemical | 0.14 |
| Co., Ltd.: Non-volatile content: 75%, 1-methoxy-2-propyl acetate: 25% | |
| Monomer mixture (polymerizable compound (b2-1) disclosed in paragraph [0111] of | 0.36 |
| JP2012-078528A, n = 1: Tripentaerythritol octaacrylate content: 85%, total of n = 2 and | |
| n = 3 of impurities is 15%) | |
| Polymer solution 1 (Structural Formula P-25 disclosed in paragraph [0058] of | 1.89 |
| JP2008-146018A: Weight-average molecular weight: 35,000, solid content: 45%, | |
| 1-methoxy-2-propyl acetate: 15%, 1-methoxy-2-propanol: 40%) | |
| Photoradically polymerizable initiator: | 0.03 |
| 2-benzyl-2-dimethylamino-1-(4-morpholinophenyl)-butanone (Irgacure (registered | |
| trademark) 379, manufactured by BASF Japan Ltd.) | |
| Photopolymerization initiator: Kayacure DETX-S (Nippon Kayaku Co., Ltd., alkyl | 0.03 |
| thioxanthone) | |
| Polymer solution 2(polymer of structural formula represented by Formula (3): solution | 0.01 |
| having weight-average molecular weight: 15,000, Non-volatile content: 30% by mass, | |
| methyl ethyl ketone: 70% by mass) | |
| 1-methoxy-2-propyl acetate | 38.73 |
| Methyl ethyl ketone | 56.80 |
| Total (parts by mass) | 100 |

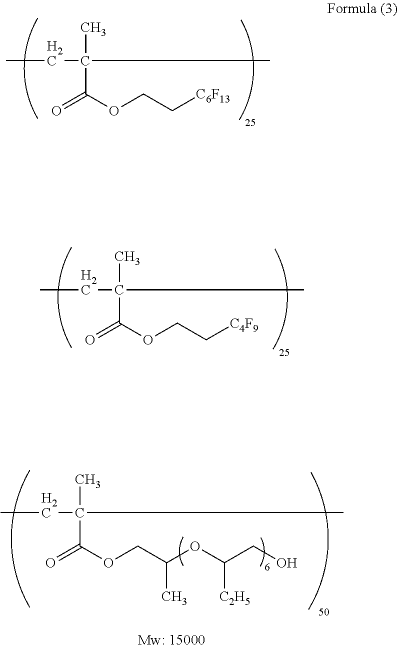

Manufacturing of Transparent Film Substrate 2

In the manufacturing of the transparent film substrate 1, a transparent film substrate 2 was manufactured in the same manner as the transparent film substrate 1, except that ZR-010 (ZrO₂, manufactured by Solar Co., Ltd.) in Table 3 was replaced with NRA-10M (TIO₂, manufactured by Taki Chemical Co., Ltd.)

### Examples 1 to 19, Examples 22 and 23, and Comparative Examples 1 and 2

<Manufacturing of Laminate>

Using each of the transparent film substrates manufactured above as a support, the surface of the photosensitive layer 1 exposed by peeling off the protective film of the transfer film selected from the transfer films A-1 to A-5 was closely attached to and laminated on the transfer film substrate to form a laminate A having a layer structure of “temporary support/photosensitive layer 1/transparent film substrate”. In the lamination conditions, a laminating roll temperature was set as 110° C., a linear pressure was set as 3 N/cm, and a transportation speed was set as 2 m/min.

Next, the surface of the photosensitive layer 2 exposed by peeling off the protective film of the transfer film selected from the transfer films B-1 to B-8 was closely attached to and laminated on the surface of the photosensitive layer 1 exposed by peeling the temporary support off from the laminate A to form a laminate B having a laminated structure of “temporary support/photosensitive layer 2/photosensitive layer 1/transparent film substrate (transparent film/COP film)”. In the lamination conditions, a laminating roll temperature was set as 110° C., a linear pressure was set as 3 N/cm, and a transportation speed was set as 2 m/min.

Then, the manufactured laminate B was irradiated with light via the temporary support under the following conditions, and the photosensitive layer 1 and the photosensitive layer 2 were cured to manufacture a laminate.

Hereinafter, the cured photosensitive layer 1 is referred to as a “resin layer 1”, the cured photosensitive layer 2 is referred to as a “resin layer 2”, and the laminate B after light irradiation is simply referred to as a “laminate”.

<Conditions>

Device: Proximity type exposure machine comprising ultra-high pressure mercury lamp (manufactured by Hitachi High-Tech Electronics Engineering Co., Ltd.)

Irradiation amount: 100 mJ/cm²

Irradiation light: i ray

### Example 20

A laminate was manufactured in the same manner as in Example 11, except that the resin layer 1 in Example 11 was not formed.

### Example 21

A laminate was manufactured in the same manner as in Example 1, except that the resin layer 1 in Example 1 was not formed.

<Evaluation>

The following measurement and evaluation were performed with respect to the laminates manufactured in Examples 1 to 23 and Comparative Examples 1 and 2. The results of measurement and evaluation are shown in Table 4.

1. Crosslink Density

The crosslink density was calculated by the following method.

(A) Calculation of Crosslink Density of First Surface Layer Portion

First, the temporary support was peeled off from the laminate, a transparent pressure sensitive adhesive tape #600 (manufactured by 3M Japan Ltd.) was attached to a surface of the exposed resin layer 2 after peeling off the temporary support, and the resin layer 2 and the resin layer 1 were peeled off from the transparent film substrate by the transparent pressure sensitive adhesive tape. The surface of the peeled resin layer 1 was measured by ATR-IR (detector: MCT, crystal: Ge, wave number resolution: 4 cm⁻¹, integration: 32 times) by using a fully automatic microscopic FT-IR system LUMOS (manufactured by Bruker Optics), a peak surface area of 810 cm⁻¹ corresponding to a peak of “double bond” corresponding to the ethylenically unsaturated group was calculated, and the surface area value was set as “Y1”.

Separately from the above, the protective films of the transfer films A-1 to A-5 were peeled off, the surface of the photosensitive layer 1 was measured by ATR-IR in the same manner as described above, the peak surface area of 810 cm⁻¹ was calculated, and the surface area value was set as “Y2”.

The crosslink density was calculated by Equation 1 using the obtained Y1 and Y2.

The crosslink density calculated by Equation 1 was a crosslink density of the ethylenically unsaturated group of the surface layer portion (first surface layer portion) of the resin layer 1 having the surface in contact with the transparent film containing ZrO₂ which is the metal oxide particles.

Crosslink density [mmol/g]=(Theoretical double bond equivalent [mmol/g] contained in 1 g of solid content of the photosensitive composition (or photosensitive layer))×(Y2−Y1)/Y2 (Equation 1)

(B) Calculation of Crosslink Density of Second Surface Layer Portion

The temporary support was peeled off from the laminate, the surface of the exposed resin layer 2 after peeling off the temporary support was measured by ATR-IR using LUMOS (manufactured by Bruker Optics), a peak surface area of 810 cm⁻¹ corresponding to a peak of “double bond” corresponding to the ethylenically unsaturated group was calculated, and the surface area value was set as “X1”.

Separately from the above, the protective films of the transfer films B-1 to B-8 were peeled off, the surface of the resin layer 2 was measured by ATR-IR in the same manner as described above, the peak surface area of 810 cm⁻¹ was calculated, and the surface area value was set as “X2”.

The crosslink density was calculated by Equation 2 using the obtained X1 and X2.

The crosslink density calculated by Equation 2 is a crosslink density of the ethylenically unsaturated group of the surface layer portion having the surface of the resin layer 2 on a side opposite to the side where the resin layer 1 is provided (second surface layer portion of the resin layer (=resin layer 1 and resin layer 2) on a side opposite to the side where the first surface layer portion is provided).

Crosslink density [mmol/g]=(Theoretical double bond equivalent [mmol/g] contained in 1 g of solid content of the photosensitive composition (or photosensitive layer))×(X2−X1)/X2 (Equation 2)

For Example 22, the crosslink density was calculated as follows.

The manufactured laminate B was exposed through the temporary support using a proximity type exposure machine (manufactured by Hitachi High-Tech Electronics Engineering Co., Ltd.) including an ultra-high pressure mercury lamp with an exposure intensity of 100 mJ/cm² (i ray), the temporary support was peeled off, and then, post exposure was further performed with an exposure intensity of 375 mJ/cm² (i ray). The crosslink density of the laminate after the post exposure was calculated by the above method.

In addition, for Example 23, the crosslink density was calculated as follows.

The manufactured laminate B was subjected to the post exposure in the same manner as in Example 22, and then post baking was performed at 145° C. for 30 minutes. The crosslink density of the laminate after the post baking was calculated by the above method.

2. Internal Stress

The manufactured laminate B was exposed through the temporary support using a proximity type exposure machine (manufactured by Hitachi High-Tech Electronics Engineering Co., Ltd.) including an ultra-high pressure mercury lamp with an exposure intensity of 100 mJ/cm² (i ray). After the exposure, the temporary support was peeled off, a surface shape in the vicinity of a center of the surface of the transparent film substrate was measured in a Micro mode by using a scanning white light interference microscope NewView5020 (manufactured by Zygo Corporation), and a difference in height between a highest (or lowest) point and a point separated from this point by 0.5 mm in a plane direction was calculated to convert into a radius of curvature of warping of the substrate.

An internal stress s of the resin layer was calculated from the following Stoney's equation by using a radius of curvature R, a modulus of elasticity of the transparent film substrate (modulus of elasticity calculated by an inclination of a linear region of an S—S curve of a tensile test) Es, a Poisson's ratio vs (0.3) of the transparent film substrate, a thickness is of the transparent film substrate, and a thickness Ta of the resin layer.

s=Es×ts²/(6×(1−vs)×R×Ta): Stoney's equation

For Example 22, the crosslink density was calculated as follows.

The manufactured laminate B was exposed through the temporary support using a proximity type exposure machine (manufactured by Hitachi High-Tech Electronics Engineering Co., Ltd.) including an ultra-high pressure mercury lamp with an exposure intensity of 100 mJ/cm² (i ray), the temporary support was peeled off, and then, post exposure was further performed with an exposure intensity of 375 mJ/cm² (i ray). The internal stress was calculated by using the laminate after the post exposure by the above method.

In addition, for Example 23, the crosslink density was calculated as follows. The manufactured laminate B was subjected to the post exposure in the same manner as in Example 22, and then post baking was performed at 145° C. for 30 minutes. The internal stress was calculated by using the laminate after the post baking by the above method.

3. Adhesiveness with Transparent Film Sub Strate

The manufactured laminate B was exposed through the temporary support using a proximity type exposure machine (manufactured by Hitachi High-Tech Electronics Engineering Co., Ltd.) including an ultra-high pressure mercury lamp with an exposure intensity of 100 mJ/cm² (i ray). After the exposure, the temporary support was peeled off to manufacture a sample for evaluation.

In Example 22, the exposure was performed in the same manner as described above, the temporary support was peeled off, and then the post exposure was performed with the exposure intensity of 375 mJ/cm² (i ray) to obtain a sample for evaluation. In addition, in Example 23, the post exposure was performed in the same manner as in Example 22, and then post baking was performed at 145° C. for 30 minutes to obtain a sample for evaluation.

Using the sample for evaluation, a cross-cut test was carried out with respect to a laminate in which 10×10 lattice cuts were made by a method based on JIS standard (K5400).

Specifically, a cutter knife is used to make cuts in a 1 mm×1 mm square lattice from the surface of the resin layer 2 of the laminate exposed by peeling of the temporary support to the resin layer 1, and the transparent pressure sensitive adhesive tape #600 (manufactured by 3M Japan Ltd.) was pressurized and bonded onto the surface of the resin layer 2. Then, one end of the bonded transparent pressure sensitive adhesive tape was grasped and pulled in the direction of 180° along the surface of the resin layer 2 to peel off the transparent pressure sensitive adhesive tape. After that, the state of the surface (peeled surface) of the resin layer 2 was visually observed, the area of the peeled portion was obtained, a ratio to the total area of a region in which the cuts are made in a lattice pattern was calculated, and the evaluation was performed according to the following evaluation standard based on the calculated value.

In the evaluation standard, A, B, or C indicates that there is no problem in practical use. The evaluation results are shown in Table 4.

<Evaluation Standard>

A: 100% of the total area of the resin layer 1 and the resin layer 2 remain to be closely attached to each other.

B: 95% to 100% of the total area of the resin layer 1 and the resin layer 2 remain to be closely attached to each other.

C: 65% to 95% of the total area of the resin layer 1 and the resin layer 2 remain to be closely attached to each other.

D: 35% to 65% of the total area of the resin layer 1 and the resin layer 2 remain to be closely attached to each other.

E: The portion where the resin layer 1 and the resin layer 2 remain to be closely attached to each otheris less than 35% of the total area.

TABLE 4

| | | Ex. 1 | Ex. 2 | Ex. 3 | Ex. 4 | Ex. 5 | Ex. 6 | Ex. 7 | Ex. 8 | Ex. 9 | Ex. 10 | Ex. 11 | Ex. 12 |
|---|---|---|---|---|---|---|---|---|---|---|---|---|---|
| Resin layer 1 | | | | | | | | | | | | | |
| Photosensitive composition | | A-1 | A-2 | A-3 | A-4 | A-1 | A-3 | A-4 | A-1 | A-3 | A-4 | A-3 | A-3 |
| Thickness [μm] | | 0.5 | 0.5 | 0.5 | 0.1 | 0.5 | 0.5 | 0.1 | 0.5 | 0.5 | 0.1 | 0.5 | 0.5 |
| Resin layer 2 | | | | | | | | | | | | | |
| Photosensitive composition | | B-3 | B-3 | B-3 | B-3 | B-4 | B-4 | B-4 | B-7 | B-7 | B-7 | B-1 | B-2 |
| Thickness [μm] | | 8.3 | 8.3 | 8.3 | 8.3 | 8.3 | 8.3 | 8.3 | 8.3 | 8.3 | 8.3 | 8.3 | 8.3 |
| Crosslink density | | | | | | | | | | | | | |
| Step | | After | After | After | After | After | After | After | After | After | After | After | After |
| | | exposure | exposure | exposure | exposure | exposure | exposure | exposure | exposure | exposure | exposure | exposure | exposure |
| Surface layer portion of the resin layer having a surface on | | 1.39 | 1.39 | 1.39 | 1.39 | 1.01 | 1.01 | 1.01 | 1.14 | 1.14 | 1.14 | 1.99 | 2.08 |
| a side opposite to a substrate side (second surface | | | | | | | | | | | | | |
| layer portion) | | | | | | | | | | | | | |
| Surface layer portion of the resin layer having a surface on | | 1.39 | 2.21 | 2.61 | 1.37 | 1.39 | 2.61 | 1.37 | 1.39 | 2.61 | 1.37 | 2.61 | 2.61 |
| a substrate side (first surface layer portion) | | | | | | | | | | | | | |
| Internal stress [MPa] | | 0.1 | 0.1 | 0.1 | 0.1 | 0.1 | 0.1 | 0.1 | 0.3 | 0.3 | 0.3 | 0.2 | 0.2 |
| Evaluation (adhesiveness) | | | | | | | | | | | | | |
| Transparent film base material 1 | | B | A | A | B | B | A | B | B | A | B | A | A |
| (containing ZrO₂) | | | | | | | | | | | | | |
| Transparent film base material 2 | | B | A | A | B | B | A | B | B | A | B | A | A |
| (containing TiO₂) | | | | | | | | | | | | | |
| | | | | | | | | | | | | Compar- | Compar- |
| | | | | | | | | | | | | ative | ative |
| | Ex. 13 | Ex. 14 | Ex. 15 | Ex. 16 | Ex. 17 | Ex. 18 | Ex. 19 | Ex. 20 | Ex. 21 | Ex. 22 | Ex. 23 | Ex. 1 | Ex.2 |
| Resin layer 1 | | | | | | | | | | | | | |
| Photosensitive composition | A-3 | A-3 | A-4 | A-4 | A-4 | A-4 | A-1 | None | None | A-3 | A-3 | A-5 | A-3 |
| Thickness [μm] | 0.5 | 0.5 | 0.1 | 0.1 | 0.1 | 0.5 | 0.5 | | | 0.5 | 0.5 | 0.5 | 0.5 |
| Resin layer 2 | | | | | | | | | | | | | |
| Photosensitive composition | B-5 | B-6 | B-1 | B-2 | B-5 | B-6 | B-6 | B-1 | B-3 | B-3 | B-3 | B-3 | B-8 |
| Thickness [μm] | 8.3 | 8.3 | 8.3 | 8.3 | 8.3 | 8.3 | 8.3 | 8.3 | 8.3 | 8.3 | 8.3 | 8.3 | 8.3 |
| Crosslink density | | | | | | | | | | | | | |
| Step | After | After | After | After | After | After | After | After | After | After | After | After | After |
| | exposure | exposure | exposure | exposure | exposure | exposure | exposure | exposure | exposure | post | post | exposure | exposure |
| | | | | | | | | | | exposure | baking | | |
| Surface layer portion of the resin layer having a surface on | 0.83 | 1.37 | 1.99 | 2.08 | 0.83 | 1.37 | 1.37 | 1.99 | 1.39 | 1.54 | 1.76 | 1.39 | 1.39 |
| a side opposite to a substrate side (second surface | | | | | | | | | | | | | |
| layer portion) | | | | | | | | | | | | | |
| Surface layer portion of the resin layer having a surface on | 2.61 | 2.61 | 1.37 | 1.37 | 1.37 | 2.61 | 1.39 | 1.85 | 1.28 | 2.91 | 3.32 | 0.45 | 2.61 |
| a substrate side (first surface layer portion) | | | | | | | | | | | | | |
| Internal stress [MPa] | 0.1 | 0.5 | 0.2 | 0.2 | 0.1 | 0.5 | 0.5 | 0.2 | 0.1 | 0.1 | 0.1 | 0.1 | 1.3 |
| Evaluation (adhesiveness) | | | | | | | | | | | | | |
| Transparent film base material 1 | A | B | B | B | B | B | C | B | B | A | A | E | E |
| (containing ZrO₂) | | | | | | | | | | | | | |
| Transparent film base material 2 | A | B | B | B | B | B | C | B | B | A | A | E | E |
| (containing TiO₂) | | | | | | | | | | | | | |

As shown in Table 4, in the examples, excellent adhesiveness could be obtained with respect to the base material containing TiO₂ particles or ZrO₂ particles. On the other hand, in Comparative Example 1 in which the crosslink density of the ethylenically unsaturated group in the first surface layer portion of the resin layer having the surface in contact with the oxide particle-containing layer does not satisfy 1.2 mmol/g, and Comparative Example 2 in which the internal stress of the resin layer exceeded 1.0 MPa, the effect of improving the adhesiveness was not observed.

Comparing between the examples, in Examples 1 to 3, the adhesiveness is improved as the crosslink density of the first surface layer portion of the resin layer 1 increases, and the crosslink density of the first surface layer portion is preferably 2.0 mmol/g or more, from a viewpoint of adhesiveness.

In addition, the resin layer 2 (photosensitive composition B3) formed in Examples 1 to 4 contains the thiol compound, and accordingly, the internal stress is maintained as a small value. The resin layer 2 (photosensitive composition B4) formed in Examples 5 to 7 contains a long-chain radically polymerizable compound instead of the thiol compound, and accordingly, the internal stress is maintained as a small value. On the other hand, the resin layer 2 (photosensitive composition B7) formed in Examples 8 to 10 contains a decreased content of the radically polymerizable compound, and accordingly, the internal stress was maintained as a small value, although it is not much as in Examples 1 to 7. The resin layer 2 (photosensitive composition B6) formed in Example 14 contains a decreased content of the radically polymerizable compound in the same manner as in Examples 8 to 10, but a ratio of the amount of the monomer to the polymer (MB ratio) was higher than in Examples 8 to 10, and accordingly, the internal stress was an even higher value. As a result, the adhesiveness is further decreased.

In addition, in Examples 15 to 18, since the monomer content in the photosensitive composition A-4 used for forming the resin layer 1 is small, the crosslink density is low, and as a result, the adhesiveness is decreased.

In Examples 20 and 21, a resin layer consisting of a single layer is formed. Even in the single-layer structure, since the photosensitive composition used for forming the resin layer contains a thiol compound, a reaction rate of C═C groups was high and the crosslink density could be maintained. As a result, the adhesiveness was improved.

In Example 22, the adhesiveness after post exposure was evaluated, and in Example 23, the adhesiveness after post baking was evaluated. Although it is considered that the crosslinking reaction proceeds, the effect of improving the adhesiveness was excellent.

What is claimed is:

1. A laminate comprising:
a base material;
an oxide particle-containing layer which is provided on the base material and contains at least one of metal oxide particle selected from the group consisting of a titanium oxide particle and a zirconium oxide particle; and
a resin layer which is a cured material of a photosensitive composition, the cured material being provided on a surface of the oxide particle-containing layer, and in which an internal stress is 1.0 MPa or less and a crosslink density D1 of an ethylenically unsaturated group of a first surface layer portion having a surface in contact with the oxide particle-containing layer is 1.2 mmol/g or more.

2. The laminate according to claim 1,
wherein the resin layer has a laminated structure of two or more layers.

3. The laminate according to claim 2,
wherein a thickness of the resin layer in contact with the oxide particle-containing layer is 1 μm or less in the laminated structure of two or more layers.

4. The laminate according to claim 1,
wherein a total thickness of the resin layer is 10 μm or less.

5. The laminate according to claim 1,
wherein, in the resin layer, the crosslink density D1 of the ethylenically unsaturated group of the first surface layer portion and a crosslink density D2 of an ethylenically unsaturated group of a second surface layer portion on a side of the resin layer opposite to a side of the first surface layer portion satisfy a relationship of D1>D2.

6. The laminate according to claim 1,
wherein the resin layer contains a resin having a thioether bond.

7. The laminate according to claim 1,
wherein the resin layer is brought into contact with at least one conductive member of an electrode for a touch panel or a wire for a touch panel to be used as a protective material of the conductive member.

8. The laminate according to claim 1,
wherein a thickness of the oxide particle-containing layer is 20 nm to 300 nm.

9. A capacitive input device comprising the laminate according to claim 7.

10. A method for manufacturing a laminate, the method comprising:
a step of forming a photosensitive layer containing a compound including an ethylenically unsaturated group on an oxide particle-containing layer of a base material having the oxide particle-containing layer, the oxide particle-containing layer containing at least one of metal oxide particle selected from the group consisting of a titanium oxide particle and a zirconium oxide particle; and
a step of exposing and curing the formed photosensitive layer to form a resin layer in which an internal stress is 1.0 MPa or less and a crosslink density of an ethylenically unsaturated group of a first surface layer portion having a surface in contact with the oxide particle-containing layer is 1.2 mmol/g or more.

11. The method for manufacturing a laminate according to claim 10,
wherein the photosensitive layer further contains a photopolymerization initiator.

12. The method for manufacturing a laminate according to claim 10,
wherein the photosensitive layer further contains a thiol compound.

13. The method for manufacturing a laminate according to claim 12,
wherein the thiol compound is a di- or higher functional thiol compound.

14. The method for manufacturing a laminate according to claim 10,
wherein the compound containing the ethylenically unsaturated group contains a compound represented by Formula (1), 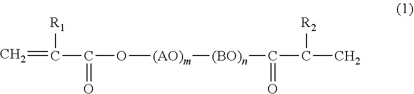
in Formula (1), R₁ and R₂ each independently represent a hydrogen atom or a methyl group, AO and BO each independently represent a different oxyalkylene group having 2 to 4 carbon atoms, and m and n each independently represent an integer of 0 or more and satisfy 4≤m+n≤30.

15. The method for manufacturing a laminate according to claim 10,
wherein, in the step of forming of the photosensitive layer, the photosensitive layer is formed on the oxide particle-containing layer by transfer using a transfer film including a temporary support and a photosensitive layer containing a compound containing an ethylenically unsaturated group.

16. The method for manufacturing a laminate according to claim 10,
wherein a thickness of the oxide particle-containing layer is 20 nm to 300 nm.
